(19) United States
(12) Patent Application Publication
(10) Pub. No.: US 2025/0194207 A1
(43) Pub. Date: Jun. 12, 2025

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 19/061,921

(22) Filed: Feb. 24, 2025

Related U.S. Application Data
(63) Continuation of application No. PCT/JP2024/000848, filed on Jan. 15, 2024.

(30) Foreign Application Priority Data
Feb. 14, 2023 (JP) 2023-020798
Aug. 9, 2023 (JP) 2023-130511

(51) Int. Cl. H10D 64/23; H10D 84/00

(52) U.S. Cl. CPC H10D 64/232; H10D 84/161

(57) ABSTRACT

Provided is a semiconductor device including an MOS gate structure, comprising: an underlying layer provided on a front surface of a semiconductor substrate or above the semiconductor substrate; an interlayer dielectric film provided above the underlying layer; a contact hole provided in the interlayer dielectric film and reaching the underlying layer from an upper surface of the interlayer dielectric film; a first alloy layer provided on a bottom portion of the contact hole; and a second alloy layer provided on a side wall of the contact hole. Provided is a manufacturing method of a semiconductor device including: depositing an initial polycrystalline film and a first initial metal film on an inner wall of the contact hole; and forming a first alloy layer on a bottom portion of the contact hole and forming a second alloy layer on a side wall of the contact hole, by heating the semiconductor substrate.

The contents of the following patent application(s) are incorporated herein by reference:
NO. 2023-020798 filed in JP on Feb. 14, 2023
NO. 2023-130511 filed in JP on Aug. 9, 2023
NO. PCT/JP2024/000848 filed in WO on Jan. 15, 2024.

### BACKGROUND

### 1. Technical Field

The present invention relates to a semiconductor device and a manufacturing method of the semiconductor device.

### 2. Related Art

Patent document 1 discloses a semiconductor device provided with a silicide layer in a contact hole.

### PRIOR ART DOCUMENTS

### Patent Document

Patent Document 1: Japanese Patent Application Publication No. 2003-318396

### BRIEF DESCRIPTION OF THE DRAWINGS

FIG. 1A shows an example of a top view of a semiconductor device 100.

FIG. 1B shows an example of an a-a′ cross section in FIG. 1A.

FIG. 2A shows a top view of a variation example of the semiconductor device 100.

FIG. 2B shows a top view of a variation example of the semiconductor device 100.

FIG. 2C shows a b-b′ cross section of a variation example of the semiconductor device 100.

FIG. 3A is an enlarged view of a cross section of the semiconductor device 100.

FIG. 3B is an enlarged view of a cross section of the semiconductor device 100.

FIG. 3C is an enlarged view of a cross section of the semiconductor device 100.

FIG. 3D is an enlarged view of a cross section of the semiconductor device 100.

FIG. 4A is an enlarged view of a cross section of the semiconductor device 100.

FIG. 4B is an enlarged view of a cross section of the semiconductor device 100.

FIG. 4C is an enlarged view of a cross section of the semiconductor device 100.

FIG. 5A is an enlarged view of a cross section of the semiconductor device 100.

FIG. 5B is an enlarged view of a cross section of the semiconductor device 100.

FIG. 6 is an enlarged view of a cross section of the semiconductor device 100.

FIG. 7 shows an example of a b-b′ cross section in FIG. 2B.

FIG. 8 shows another example of a b-b′ cross section in FIG. 2B.

FIG. 9 is a flowchart showing an example of a manufacturing process of the semiconductor device 100.

FIG. 10A is a diagram showing an example of a manufacturing process of the semiconductor device 100.

FIG. 10B is a diagram showing an example of a manufacturing process of the semiconductor device 100.

FIG. 10C is a diagram showing an example of a manufacturing process of the semiconductor device 100.

FIG. 11A is an enlarged view of a cross section of a variation example of the semiconductor device 100.

FIG. 11B is an enlarged view of a cross section of a variation example of the semiconductor device 100.

FIG. 11C is an enlarged view of a cross section of a variation example of the semiconductor device 100.

FIG. 11D is an enlarged view of a cross section of a variation example of the semiconductor device 100.

FIG. 12 is an enlarged view of a cross section of a variation example of the semiconductor device 100.

FIG. 13A is an enlarged view of a cross section of a semiconductor device 200.

FIG. 13B is an enlarged view of a cross section of the semiconductor device 200.

FIG. 14 is a flowchart showing an example of a manufacturing process of the semiconductor device 200.

FIG. 15A is a diagram showing an example of a manufacturing process of the semiconductor device 200.

FIG. 15B is a diagram showing an example of a manufacturing process of the semiconductor device 200.

FIG. 15C is a diagram showing an example of a manufacturing process of the semiconductor device 200.

FIG. 16A is an enlarged view of a cross section of a variation example of the semiconductor device 200.

FIG. 16B is an enlarged view of a cross section of a variation example of the semiconductor device 200.

FIG. 16C is an enlarged view of a cross section of a variation example of the semiconductor device 200.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It should be noted that the +Z axis direction and the −Z axis direction are directions opposite to each other. If the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis direction and the Y axis direction.

In the present specification, a description of a P+ type or an N+ type means a higher doping concentration than that of the P type or the N type, and a description of a P− type or an N− type means a lower doping concentration than that of the P type or the N type.

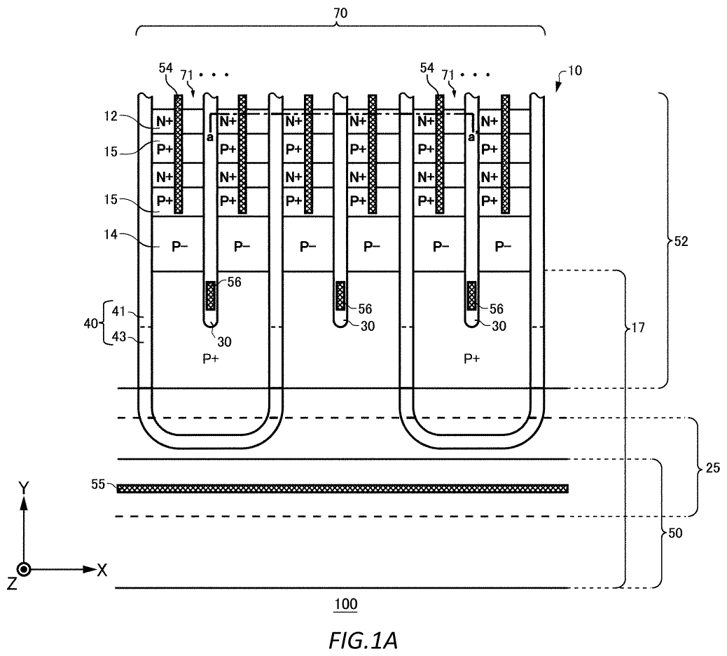

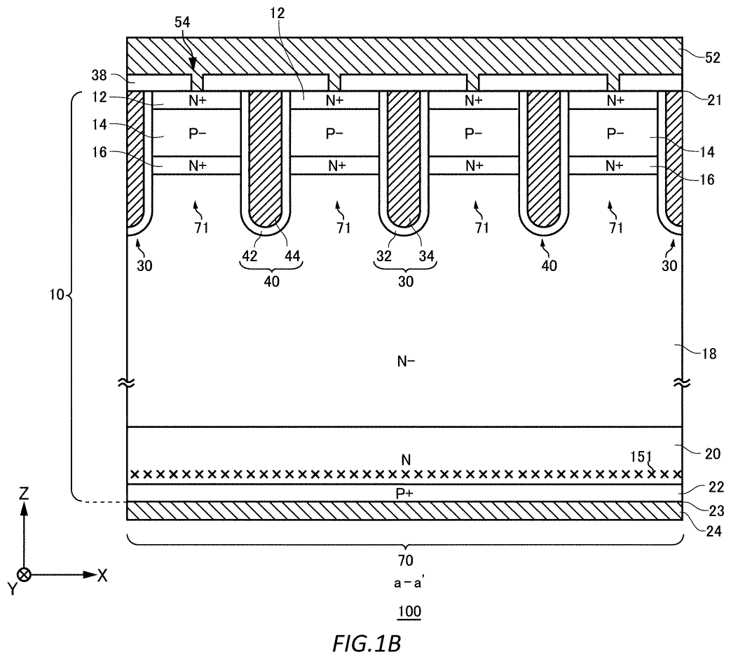

FIG. 1A illustrates an example of the top view of a semiconductor device 100. The semiconductor device 100 in the present example is a semiconductor chip that includes a transistor portion 70. The semiconductor device 100 is not limited to a transistor as long as it is a semiconductor element in which a semiconductor substrate 10 has a MOS gate structure.

The transistor portion 70 is a region obtained by projecting a collector region 22 provided on a back surface side of a semiconductor substrate 10 onto an upper surface of the semiconductor substrate 10. The collector region 22 will be described below. The transistor portion 70 includes a transistor such as an IGBT. In the present example, the transistor portion 70 is an IGBT. It is to be noted that the transistor portion 70 may be other transistors such as an MOSFET.

The present figure illustrates a region around an active portion of the semiconductor device 100 and other regions are omitted. For example, an edge termination structure portion may be provided in a region on a negative side in the Y axis direction in the semiconductor device 100 in the present example. The edge termination structure portion reduces electric field strength on an upper surface side of the semiconductor substrate 10. The edge termination structure portion has, for example, a guard ring, a field plate, a RESURF, and a structure combining these. It should be noted that although the present example describes an edge on the negative side in the Y axis direction for convenience, the same applies to other edges of the semiconductor device 100.

The semiconductor substrate 10 is a substrate that is formed of a semiconductor material. The semiconductor substrate 10 may be a silicon substrate or may be a silicon carbide substrate. The semiconductor substrate 10 may be a III-V compound such as GaN, Ga₂O₃, C or the like. The semiconductor substrate 10 in the present example is the silicon substrate. It is to be noted that when simply referred to as a top view in the present specification, it means that the upper surface side of the semiconductor substrate 10 is viewed from above. As will be described later, the semiconductor substrate 10 includes a front surface 21 and a back surface 23.

The semiconductor device 100 in the present example includes, at a front surface 21 of the semiconductor substrate 10, a gate trench portion 40, a dummy trench portion 30, an emitter region 12, a base region 14, a contact region 15, and a well region 17. In addition, the semiconductor device 100 in the present example includes an emitter electrode 52 and a gate metal layer 50 which are provided above the front surface 21 of the semiconductor substrate 10. The emitter electrode 52 and the gate metal layer 50 are an example of a front surface side metal layer. The gate trench portion 40 is an example of the MOS gate structure provided in the semiconductor device 100. It is to be noted that although the semiconductor device 100 of the present example is a transistor including the MOS gate structure, the semiconductor device 100 may alternatively be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above the connection portion 25 and the well region 17.

The emitter electrode 52 and the gate metal layer 50 are formed of a material containing metal. At least a partial region of the emitter electrode 52 may be formed of metal such as aluminum (Al) and copper (Cu) or of a metal alloy such as an aluminum-silicon alloy (AlSi) or an aluminum-silicon-copper alloy (AlSiCu). At least a partial region of the gate metal layer 50 may be formed of metal such as aluminum (Al) and copper (Cu) or a metal alloy such as an aluminum-silicon alloy (AlSi) and an aluminum-silicon-copper alloy (AlSiCu). The emitter electrode 52 and the gate metal layer 50 are provided separately from each other.

The emitter electrode 52 and the gate metal layer 50 are provided with an interlayer

dielectric film 38 sandwiched therebetween, above the semiconductor substrate 10. The interlayer dielectric film 38 is omitted in FIG. 1A. A contact hole 54, a contact hole 55, and a contact hole 56 are provided through the interlayer dielectric film 38.

The contact hole 55 electrically connects the gate metal layer 50 and the gate conductive portion in the transistor portion 70 through the connection portion 25. A plug layer formed of tungsten, copper or the like may be provided inside the contact hole 55. The plug layer will be described later.

The contact hole 56 connects the emitter electrode 52 with a dummy conductive portion inside the dummy trench portion 30. A plug layer formed of tungsten, copper or the like may be provided inside the contact hole 56.

The connection portion 25 is connected to a front surface side metal layer such as the emitter electrode 52 or the gate metal layer 50. In an example, the connection portion 25 is provided between the gate metal layer 50 and the gate conductive portion. The connection portion 25 of the present example may be provided extending in the X axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is formed of a conductive material such as polysilicon doped with an impurity. The connection portion 25 in the present example is polysilicon doped with an impurity of the N type (N+). The connection portion 25 is provided above the front surface 21 of the semiconductor substrate 10 via an dielectric film such as an oxide film.

The gate trench portions 40 are an example of a plurality of trench portions extending in a predetermined extending direction on the front surface 21 side of the semiconductor substrate 10. The gate trench portions 40 are arrayed at a predetermined interval along a predetermined array direction (the X axis direction in the present example). The gate trench portion 40 in the present example may have two extending portions 41 which extend along an extending direction (the Y axis direction in the present example) parallel to the front surface 21 of the semiconductor substrate 10 and perpendicular to the array direction, and a connecting portion 43 which connects the two extending portions 41.

At least part of the connecting portion 43 is preferably formed in a curved shape. Connecting end portions of the two extending portions 41 of the gate trench portion 40 can reduce electric field strength at the end portions of the extending portions 41. The gate metal layer 50 may be electrically connected to the gate conductive portion through the connection portion 25 in the connecting portion 43 of the gate trench portion 40. In another example, rather than providing the connection portion 25, the contact hole 55 may be provided exactly on the extending portion 41 or the connecting portion 43 to connect the gate metal layer 50 and the gate conductive portion.

Alternatively, the gate metal layer 50 may not be provided within the range of FIG. 1A and the gate metal layer 50 or the gate pad which will be described below and the connection portion 25 may be connected via the contact hole 55 outside the range of FIG. 1A.

The dummy trench portions 30 are an example of the plurality of trench portions extending in the predetermined extending direction on the front surface 21 side of the semiconductor substrate 10. The dummy trench portion 30 is a trench portion which is electrically connected to the emitter electrode 52. Similar to the gate trench portions 40, the dummy trench portions 30 are arrayed at predetermined intervals along a predetermined array direction (the X axis direction in the present example). Although the dummy trench portion 30 of the present example has an I shape on the front surface 21 of the semiconductor substrate 10, it may have a U shape on the front surface 21 of the semiconductor substrate 10 similar to the gate trench portion 40. That is, the dummy trench portion 30 may include two extending portions extending along the extending direction and a connecting portion connecting the two extending portions.

The transistor portion 70 of the present example has a structure in which two gate trench portions 40 and two dummy trench portions 30 are arrayed repetitively. That is, the transistor portion 70 of the present example includes the gate trench portions 40 and the dummy trench portions 30 where the ratio thereof is 1:1. For example, the transistor portion 70 includes one dummy trench portion 30 between two extending portions 41.

It is to be noted that the ratio between the gate trench portions 40 and the dummy trench portions 30 is not limited to that in the present example. The ratio of the gate trench portions 40 may be larger than the ratio of the dummy trench portions 30, or the ratio of the dummy trench portions 30 may be larger than the ratio of the gate trench portions 40. The ratio between the gate trench portions 40 and the dummy trench portions 30 may be 2:3, or may be 2:4. In addition, the transistor portion 70 may not have the dummy trench portions 30 with all trench portions being the gate trench portions 40. In another example, the trench portions may be provided in a discrete manner. In yet another example, the trench portion may include intersection portion in the active portion 120. The trench portion in a discrete manner may refer to a state where circular trench portions not including extending portions are provided discretely in a top view, for example. In this case, the shape of the trench portion in a top view may be a square shape, a hexagonal shape or the like, or other shapes. Alternatively, it may refer to a state where the trench portions each of which is formed by connecting both ends of the extending portion are provided discretely. In addition,, an array of each trench portion in a top view may be a square shape, a hexagonal shape or the like. The trench portion including intersection portion in the active portion 120 may refer to a state where the conductive portions in the trenches are electrically connected.

The well region 17 is a region of a second conductivity type which is provided in a front surface 21 side of the semiconductor substrate 10 relative to a drift region 18 which will be described below. The well region 17 is an example of the well region provided in a peripheral side of the active portion 120. The active portion 120 will be described below. The well region 17 is of the P+ type as an example. The well region 17 is provided in a predetermined range from an end portion of the active portion 120 at a side where the gate metal layer 50 is provided. A diffusion depth of the well region 17 may be deeper than depths of the gate trench portion 40 and the dummy trench portion 30. Parts of regions of the gate trench portion 40 and the dummy trench portion 30 on a gate metal layer 50 side are provided in the well region 17. Bottoms of ends in the extending direction of the gate trench portion 40 and the dummy trench portion 30 may be covered with the well region 17.

The contact hole 54 is provided above each region of the emitter region 12 and the contact region 15 in the transistor portion 70. The contact hole 54 is not provided above well regions 17 provided at both ends in the Y axis direction. In this way, the interlayer dielectric film is provided with one or more contact holes 54. One or more contact holes 54 may be provided to extend in the extending direction.

A mesa portion 71 is a mesa portion provided in direct contact with the trench portion in a plane parallel to the front surface 21 of the semiconductor substrate 10. The mesa portion may be a part of the semiconductor substrate 10 sandwiched between two adjacent trench portions, and may be a part from the front surface 21 of the semiconductor substrate 10 to a depth of the lowermost bottom portion of each trench portion. An extending portion of each trench portion may be defined as one trench portion. That is, a region interposed between two extending portions may be referred to as the mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the contact region 15 at the front surface 21 of the semiconductor substrate 10. In the present example, in the mesa portion 71, emitter regions 12 and contact regions 15 are alternately provided in the extending direction. In another example, in the mesa portion 71, the emitter region 12 may be arranged in contact with the trench portion and the contact region 15 may be arranged in contact with the emitter region 12 and spaced apart from the trench portion.

The base region 14 is a region of the second conductivity type which is provided in the front surface 21 side of the semiconductor substrate 10. The base region 14 is of the P-type as an example. The base regions 14 may be provided at both end portions of the mesa portion 71 in the Y axis direction at the front surface 21 of the semiconductor substrate 10. Note that FIG. 1A illustrates only one end portion in the Y axis direction of the base region 14.

The emitter region 12 is a region of a first conductivity type having a higher doping concentration than the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may be or may not be in contact with the dummy trench portion 30. The emitter region 12 in the present example is in contact with the dummy trench portion 30.

The contact region 15 is a region of the second conductivity type provided above the base region 14 and having a higher doping concentration than the base region 14. The contact region 15 in the present example is of the P+type as an example. The contact region 15 in the present example is provided at the front surface 21 in the mesa portion 71. The contact region 15 may be provided in the X axis direction from one to another of the two trench portions sandwiching the mesa portion 71. The contact region 15 may be or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1B illustrates an example of the cross section a-a′ in FIG. 1A. The cross section a-a′ is an XZ plane which passes through the emitter region 12 in the transistor portion 70. The semiconductor device 100 in the present example has the semiconductor substrate 10, an interlayer dielectric film 38, the emitter electrode 52, and the collector electrode 24 on the cross section a-a′. The collector electrode 24 is an example of a back surface side metal layer provided in contact with the back surface 23 of the semiconductor substrate 10. The emitter electrode 52 is provided above the semiconductor substrate 10 and the interlayer dielectric film 38.

The drift region 18 is a region of the first conductivity type which is provided in the semiconductor substrate 10. The drift region 18 in the present example is of the N-type as an example. The drift region 18 may be a region which has remained without other doping regions formed in the semiconductor substrate 10. In other words, the doping concentration of the drift region 18 may be the doping concentration of the semiconductor substrate 10.

A buffer region 20 is a region of the first conductivity type which is provided on a back surface 23 side of the semiconductor substrate 10 relative to the drift region 18. The buffer region 20 in the present example is of the N type as an example. A doping concentration in the buffer region 20 is higher than the doping concentration in the drift region 18. The buffer region 20 may function as a field stop layer which prevents a depletion layer extending from a lower surface side of the base region 14 from reaching the collector region 22 of the second conductivity type. It should be noted that the buffer region 20 may be omitted.

The collector region 22 is provided below the buffer region 20 in the transistor portion 70. The collector region 22 is of the second conductivity type. The collector region 22 in the present example is of the P+ type as an example.

The collector electrode 24 is provided on the back surface 23 of the semiconductor substrate 10. The collector electrode 24 is formed of a conductive material such as metal. The material of the collector electrode 24 may be the same as or may be different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may be or may not be in contact with the dummy trench portion 30.

The accumulation region 16 is a region of a first conductivity type provided in the front surface 21 side of the semiconductor substrate 10 as compared to the drift region 18. The accumulation region 16 in the present example is of the N+ type as an example. It is to be noted that the accumulation region 16 may not be provided.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. An ion implantation dose amount of the accumulation region 16 may be 1.0 E+12 cm⁻² or more and 1.0 E+13 cm⁻² or less. Alternatively, the ion implantation dose amount of the accumulation region 16 may be 3.0 E+12 cm⁻² or more and 6.0 E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided on the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. A configuration in which a trench portion penetrates a doping region is not limited to a configuration which is manufactured by forming a doping region and forming a trench portion in this order. The configuration of the trench portion passing through the doping region includes a configuration of the doping region being formed between the trench portions after forming the trench portion.

The gate trench portion 40 has a gate trench, a gate dielectric film 42, and a gate conductive portion 44 which are formed at the front surface 21. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21. An upper end of the gate conductive portion 44 may be at the same height as the front surface 21, may be at a position lower than that of the front surface 21, or may be at a position upper than that of the front surface 21.

The gate conductive portion 44 includes a region opposing the adjacent base region 14 on the side of the mesa portion 71 by sandwiching the gate dielectric film 42 in a depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on the front surface 21 side. The dummy dielectric film 32 is provided to cover an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21. An upper end of the dummy conductive portion 34 may be at the same height as the front surface 21, may be at a position lower than that of the front surface 21, or may be at a position upper than that of the front surface 21.

The interlayer dielectric film 38 is provided above the front surface 21 of the semiconductor substrate 10. The interlayer dielectric film 38 of the present example is provided in contact with the front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may be provided to pass through the interlayer dielectric film 38. A film thickness of the interlayer dielectric film 38 is, for example, 1.0 μm, but is not limited to this.

The interlayer dielectric film 38 may be a silicon oxide film. The interlayer dielectric film 38 may be a BPSG (Boro-phospho Silicate Glass) film, may be a BSG (borosilicate glass) film, or may be a PSG (Phosphosilicate glass) film. The interlayer dielectric film 38 may also include a high temperature silicon oxide (HTO: High Temperature Oxide) film.

The back surface side lifetime control region 151 may be provided in the transistor portion 70. It is to be noted that the back surface side lifetime control region 151 may be omitted. The back surface side lifetime control region 151 is a region where a lifetime killer has intentionally been formed by implanting an impurity inside the semiconductor substrate 10, or the like. As an example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements configuring the semiconductor substrate 10, or dislocation. Furthermore, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. Alternatively, the lifetime killer concentration may be a chemical concentration of the noble gas element such as helium and neon, or may be a chemical concentration of the metal element such as platinum.

The back surface side lifetime control region 151 is provided closer to the back surface 23 side than the center of the semiconductor substrate 10 in the depth direction of the semiconductor substrate 10. The back surface side lifetime control region 151 of the present example is provided in the buffer region 20. The back surface side lifetime control region 151 of the present example is provided in an entire region of the semiconductor substrate 10 in the XY plane, and can be formed without using a mask. The back surface side lifetime control region 151 may be provided in a part of the semiconductor substrate 10 in the XY plane. An impurity dose amount for forming the back surface side lifetime control region 151 may be 0.5 E+10 cm⁻² or more and 1.0 E+14 cm⁻² or less, or may be 5.0 E+10 cm⁻² or more and 1.0 E+13 cm⁻² or less.

The back surface side lifetime control region 151 may be formed by implantation from the back surface 23 side of the semiconductor substrate 10. This can facilitate to avoid an influence on the front surface 21 side of the semiconductor substrate 10. For example, the back surface side lifetime control region 151 is formed by irradiating helium or proton from the back surface 23 side of the semiconductor substrate 10. Here, whether the back surface side lifetime control region 151 is formed by implantation from the front surface 21 side of the semiconductor substrate 10 or formed by implantation from the back surface 23 side of the semiconductor substrate 10 can be determined by an SRP method or measurement of leak currents to obtain an state of the front surface 21 side.

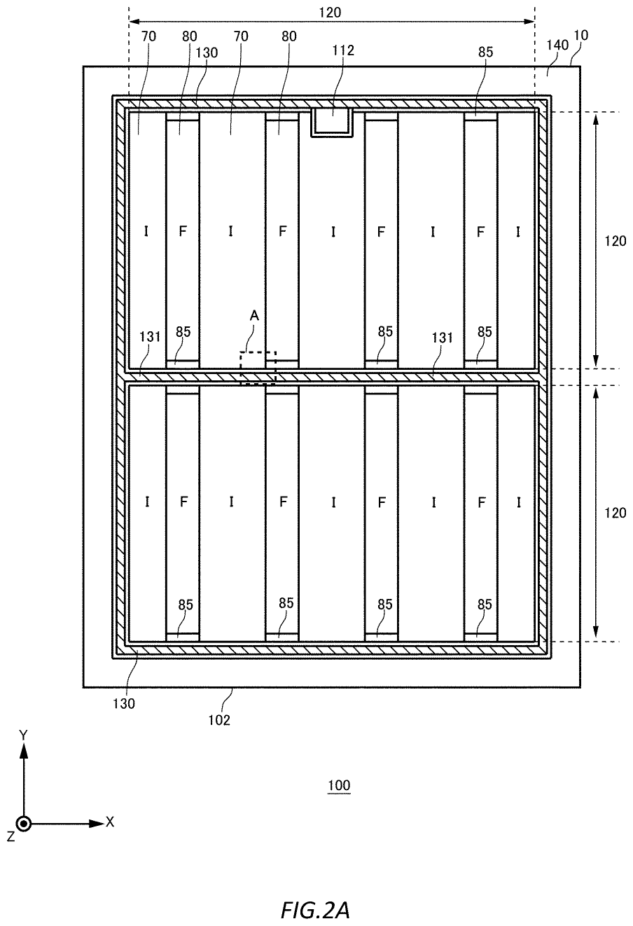

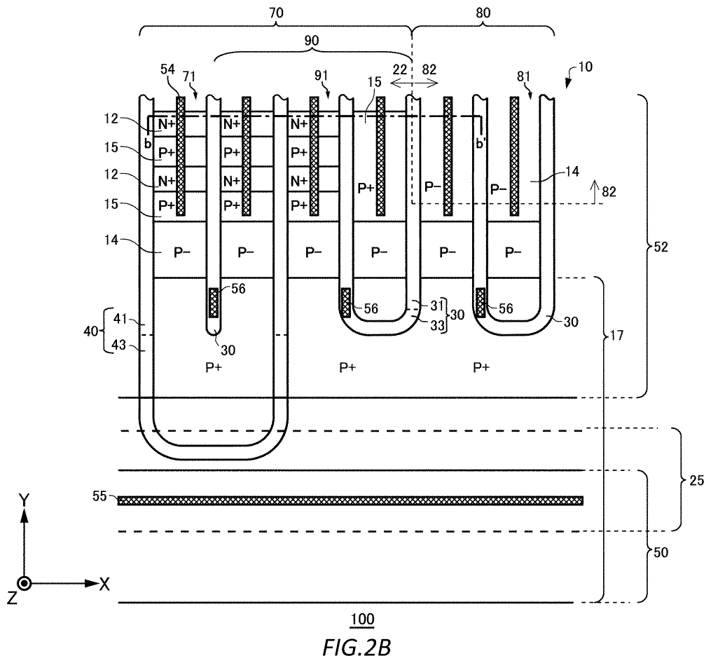

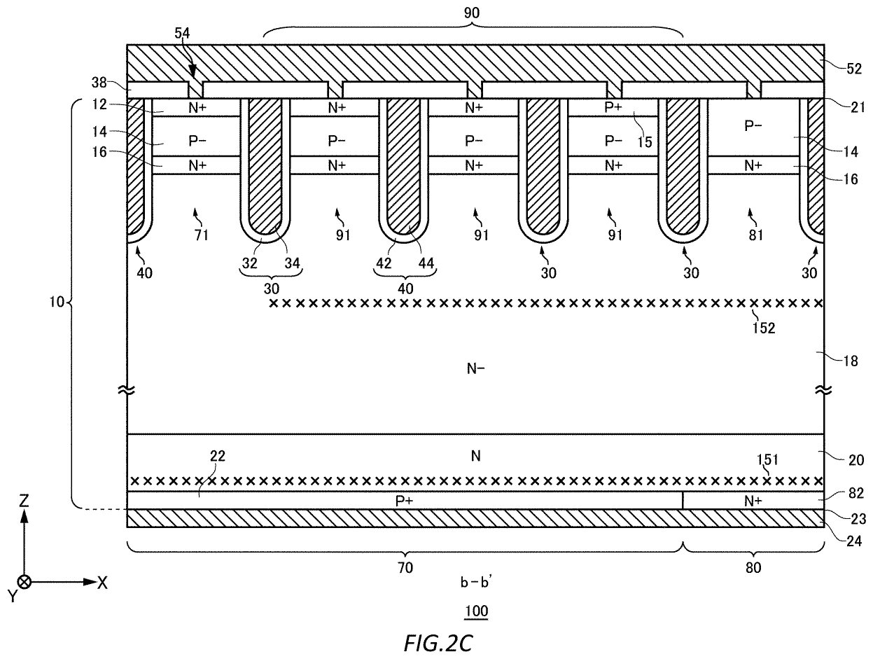

FIG. 2A shows a top view of a variation example of the semiconductor device 100. The present example illustrates merely some members of the semiconductor device 100, and omits some members.

The semiconductor substrate 10 has an end side 102 in a top view. The semiconductor substrate 10 in the present example includes two sets of end sides 102 facing each other in a top view. In the present example, the X axis and the Y axis are parallel to any of the end sides 102.

The semiconductor substrate 10 is provided with an active portion 120. The active portion 120 is a region where a principal current flows in the depth direction between the front surface 21 and the back surface 23 of the semiconductor substrate 10 when the semiconductor device 100 operates. An emitter electrode 52 is provided above the active portion 120, but is omitted in the present figure.

The active portion 120 is provided with at least one of a transistor portion 70 including a transistor element such as an IGBT, or a diode portion 80 including a diode element such as a free wheeling diode (FWD). In the example of FIG. 2A, the transistor portion 70 and the diode portion 80 are alternately arranged along a predetermined array direction (the X axis direction in the present example) on the front surface 21 of the semiconductor substrate 10. The active portion 120 in another example may be provided with only one of the transistor portion 70 and the diode portion 80.

In the present example, a region where the transistor portion 70 is arranged is denoted by a symbol “I”, and a region where the diode portion 80 is arranged is denoted by a symbol “F”. The transistor portion 70 and the diode portion 80 may each have a longitudinal length in an extending direction. In other words, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80, and a longitudinal direction of each trench portion to be described later may be the same.

The diode portion 80 is a region where a cathode region 82 provided on the back surface 23 side of the semiconductor substrate 10 is projected onto the front surface 21 of the semiconductor substrate 10. The cathode region 82 will be described later. On the back surface 23 of the semiconductor substrate 10, a P+ type of collector region 22 may be provided in a region other than the cathode region 82. In the present specification, the diode portion 80 may also include an extension region 85 where the diode portion 80 extends to a gate runner described below in the Y axis direction. On the back surface 23 of the extension region 85, the collector region 22 may be provided.

The semiconductor device 100 may have one or more pads above the semiconductor substrate 10. The semiconductor device 100 of the present example has a gate pad 112. The semiconductor device 100 may include a pad such as an anode pad and a cathode pad. Each pad is arranged in the vicinity of the end side 102. The vicinity of the end side 102 refers to a region between the end side 102 and the emitter electrode 52 in a top view. When the semiconductor device 100 is mounted, each pad may be connected to an external circuit via a wiring line such as a wire.

A gate potential is applied to the gate pad 112. The gate pad 112 is electrically connected to the gate conductive portion 44 of the gate trench portion 40 of the active portion 120. The semiconductor device 100 includes a gate runner that connects the gate pad 112 and the gate trench portion 40. In FIG. 2A, the gate runner is hatched with diagonal lines.

The gate runner of the present example has an outer circumferential gate runner 130 and an inter-active-portion gate runner 131. The gate runner may be configured by either one of the gate metal layer 50 or the connection portion 25, or a combination of both of them as appropriate. The outer circumferential gate runner 130 and the inter-active-portion gate runner 131 may have the same configuration or may have a different configuration. The outer circumferential gate runner 130 is arranged between the active portion 120 and the end side 102 of the semiconductor substrate 10 in a top view. The outer circumferential gate runner 130 of the present example surrounds the active portion 120 in the top view. A region surrounded by the outer circumferential gate runner 130 in the top view may be the active portion 120. Further, the outer circumferential gate runner 130 is connected to the gate pad 112. The outer circumferential gate runner 130 is arranged above the semiconductor substrate 10. The outer circumferential gate runner 130 may be configured of the gate metal layer 50 and the connection portion 25.

The inter-active-portion gate runner 131 is provided between a plurality of active portions 120. In FIG. 2A, two active portions 120 are arranged side by side in the Y axis direction. Providing the inter-active-portion gate runner 131 between the plurality of active portions 120 inside the semiconductor substrate 10 can reduce a variation in wiring length from the gate pad 112 for each region of the semiconductor substrate 10.

The inter-active-portion gate runner 131 is connected to the gate trench portion of the active portion 120. The inter-active-portion gate runner 131 is arranged above the semiconductor substrate 10. The inter-active-portion gate runner 131 of the present example is configured of the gate metal layer 50 and the connection portion 25. The gate metal layer 50 may be a metal layer including aluminum or the like.

The inter-active-portion gate runner 131 may be connected to the outer circumferential gate runner 130. The inter-active-portion gate runner 131 of the present example is provided extending in the X axis direction from one outer circumferential gate runner 130 to another outer circumferential gate runner 130 substantially at the center of the Y axis direction, so as to cross the active portion 120. When the active portion 120 is divided by the inter-active-portion gate runner 131, the transistor portion 70 and the diode portion 80 may be alternately arranged in the X axis direction in each divided region.

The edge termination structure portion 140 is provided in the front surface 21 of the semiconductor substrate 10. The edge termination structure portion 140 is provided between the active portion 120 and the end side 102 in a top view. The edge termination structure portion 140 in this example is arranged between the outer circumferential gate runner 130 and the end side 102. The edge termination structure portion 140 reduces electric field strength on the front surface 21 side of the semiconductor substrate 10. The edge termination structure portion 140 may include at least one of a guard ring, a field plate, and an RESURF which are annularly provided to enclose the active portion 120.

FIG. 2B illustrates a top view of the variation example of the semiconductor device 100. The semiconductor device 100 of the present example includes the transistor portion 70 and a diode portion 80. The present figure is an enlarged view of the upper surface of the region A in FIG. 2A.

The semiconductor device 100 of the present example includes a gate trench portion 40, a dummy trench portion 30, an emitter region 12, a base region 14 a contact region 15, and a well region 17 provided inside the front surface 21 side of the semiconductor substrate 10. Each of the gate trench portion 40 and the dummy trench portions 30 is one example of the trench portion. Similar to the gate trench portion 40, the dummy trench portion 30 of the present

example may have a U shape on the front surface 21 of the semiconductor substrate 10. That is, the dummy trench portion 30 may include two extending portions extending along the extending direction 31 and a connecting portion 33 connecting the two extending portions 31.

The semiconductor device 100 of the present example includes the emitter electrode 52 and the gate metal layer 50 provided above the front surface 21 of the semiconductor substrate 10. The emitter electrode 52 and the gate metal layer 50 are provided separately from each other. The transistor portion 70 of this example includes a boundary region 90 positioned on the boundary between the transistor portion 70 and the diode portion 80. A region of the transistor portion 70 other than the boundary region 90, that is, a region spaced apart from the diode portion 80 may be referred to as a main region.

The boundary region 90 is a region provided between the main region of the transistor portion 70 and the diode portion 80 and adjacent to the diode portion 80. The boundary region 90 includes the contact region 15 on the front surface 21 of the semiconductor substrate 10. In an example, the trench portions of the boundary region 90 include the gate trench portion 40 and the dummy trench portion 30. The boundary region 90 of the present example is arranged such that both ends in the X axis direction are the dummy trench portions 30, while it may be arranged in another example such that one end is the dummy trench portion 30 and the other end is the gate trench portion 40 in the X axis direction.

The contact hole 54 is provided above the base region 14 in the diode portion 80. The contact hole 54 is provided above the contact region 15 in the boundary region 90. No contact holes 54 are provided above the well regions 17 provided at both ends in the Y axis direction.

The mesa portion 91 is provided in the boundary region 90. The mesa portion 91 includes the emitter region 12 and the contact region 15 on the front surface 21 of the semiconductor substrate 10, similarly to the main region of the transistor portion 70. The boundary region 90 may have a buffer structure different from that of the main region for including the structures of both of the transistor portion 70 and the diode portion 80. As an example of the buffer structure, the mesa portion 91 closest to the diode portion 80 may not include the emitter region 12. In addition, across a plurality of mesa portions 91, the base region 14 may be exposed to the front surface 21 of the semiconductor substrate 10. The mesa portion 91 in the present example includes the base region 14 and the well region 17 in the negative side of the Y axis direction.

The mesa portion 81 is provided in a region sandwiched between the dummy trench portions 30 adjacent to each other in the diode portion 80. The mesa portion 81 has the base region 14 at the front surface 21 of the semiconductor substrate 10. The mesa portion 81 of the present example includes the well region 17 on the negative side in the Y axis direction.

The emitter region 12 is provided in the mesa portion 71 while it may not be provided in the mesa portion 81 and the mesa portion 91 closest to the diode portion 80. The contact region 15 is provided in the mesa portion 71 and the mesa portion 91, but does not need to be provided in the mesa portion 81.

FIG. 2C shows a b-b′ cross section of a variation example of the semiconductor device 100. This figure corresponds to the b-b′ cross section of FIG. 2B. The semiconductor device 100 of the present example includes the back surface side lifetime control region 151 and a front surface side lifetime control region 152. However, the semiconductor device 100 may not include one of the back surface side lifetime control region 151 or the front surface side lifetime control region 152. The semiconductor device 100 of the present example includes the collector region 22 and the cathode region 82 at the lower surface side of the buffer region 20, that is, at the back surface 23 side of the semiconductor substrate 10.

The emitter region 12 is provided above the base region 14 in the mesa portion 71. The emitter region 12 is provided in contact with the gate trench portion 40 in the mesa portion 71. In another cross section, the emitter region 12 may be provided on the front surface 21 of the mesa portion 71.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 of the present example is provided in the entire region of the transistor portion 70 and the diode portion 80. It is to be noted that the accumulation region 16 does not need to be provided in the diode portion 80.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary region 90 of the present example.

The back surface side lifetime control region 151 is provided in both of the transistor portion 70 and the diode portion 80. With this configuration, in the semiconductor device 100 in the present example, a recovery speed in the diode portion 80 can be raised, and a switching loss can be further improved. The back surface side lifetime control region 151 may be formed by a method similar to that of the back surface side lifetime control region 151 in other examples.

The front surface side lifetime control region 152 is provided in the front surface 21 side as compared to the center of the semiconductor substrate 10 in the depth direction of the semiconductor substrate 10. The front surface side lifetime control region 152 of the present example is provided in the drift region 18. The front surface side lifetime control region 152 is provided in both of the transistor portion 70 and the diode portion 80. The front surface side lifetime control region 152 may be provided in the diode portion 80 and the boundary region 90 and may not be provided in a part of the transistor portion 70. In another example, the front surface side lifetime control region 152 may be provided in the entire region of the transistor portion 70, may not be provided in the entire region of the transistor portion 70, or may not be provided in a part of or the entire region of diode portion 80. The front surface side lifetime control region 152 can suppress hole injection from the base region 14 of the diode portion 80 and the contact regions 15 of the transistor portion 70 to reduce reverse recovery loss.

The front surface side lifetime control region 152 may be formed by any of the methods for forming the back surface side lifetime control region 151. The element, the dose amount, and the like for forming the back surface side lifetime control region 151 may be the same as or different from those for forming the front surface side lifetime control region 152. The case where the lifetime is adjusted in the entire range of the Z axis direction of the semiconductor substrate 10 by irradiation of an electron beam or the like may be regarded as an example of forming the front surface side lifetime control region 152.

The front surface side lifetime control region 152 of the present example is provided to extend from the diode portion 80 to the boundary region 90. The front surface side lifetime control region 152 may be formed by an irradiation from the front surface 21 of the semiconductor substrate 10. The front surface side lifetime control region 152 may alternatively be formed by an irradiation from the back surface 23 side of the semiconductor substrate 10. The front surface side lifetime control region 152 of the present example is provided below the gate trench portion 40. Due to particle beams or the like for forming the front surface side lifetime control region 152 passing through the MOS gate structure of the semiconductor device 100, a defect may be generated at an interface between the gate oxide film and the semiconductor substrate.

The semiconductor device 100 may be a power semiconductor device for performing power control and the like. The semiconductor device 100 of the present example may have a vertical semiconductor structure in which a back surface side metal layer is provided on the back surface 23 side of the semiconductor substrate 10.

It is to be noted that in the present example, an RC-IGBT having a trench gate structure is described as an example of the semiconductor device 100. It is to be noted that the semiconductor device 100 may be a semiconductor device having a planar gate structure, or may be other semiconductor devices such as a diode. The semiconductor device 100 may include an N-channel MOSFET or P-channel MOSFET.

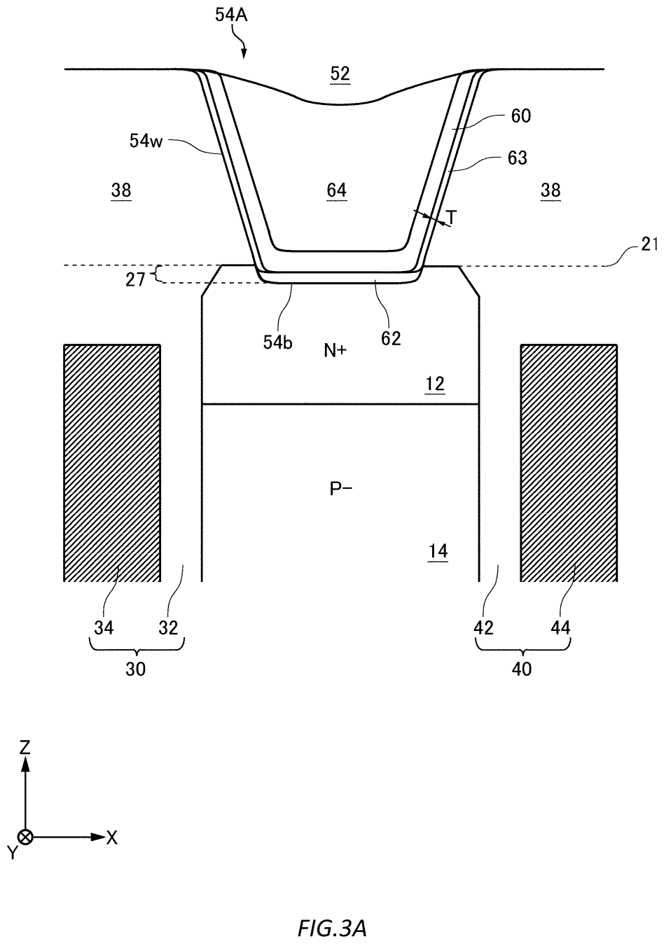

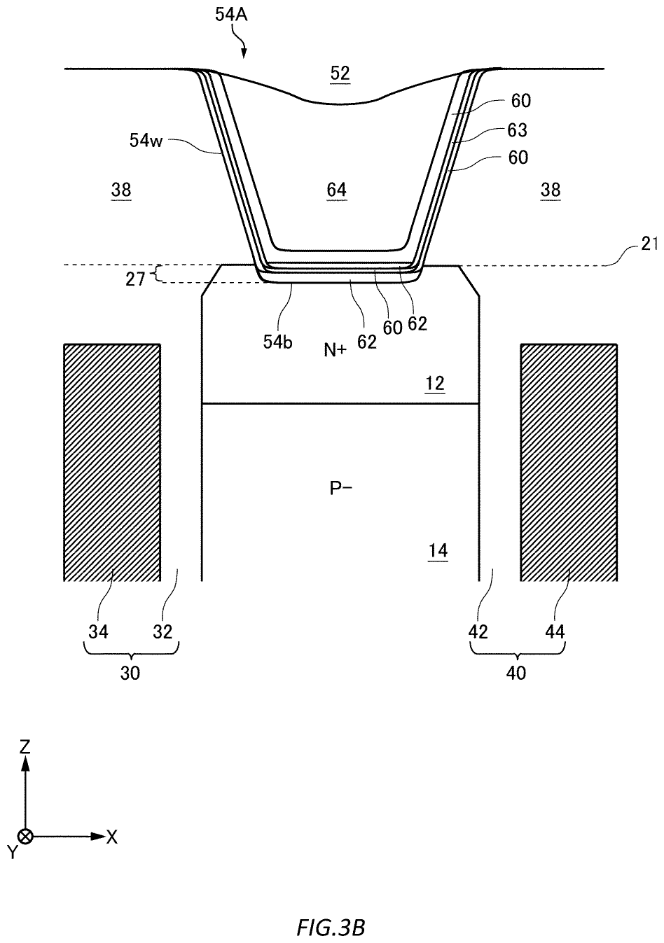

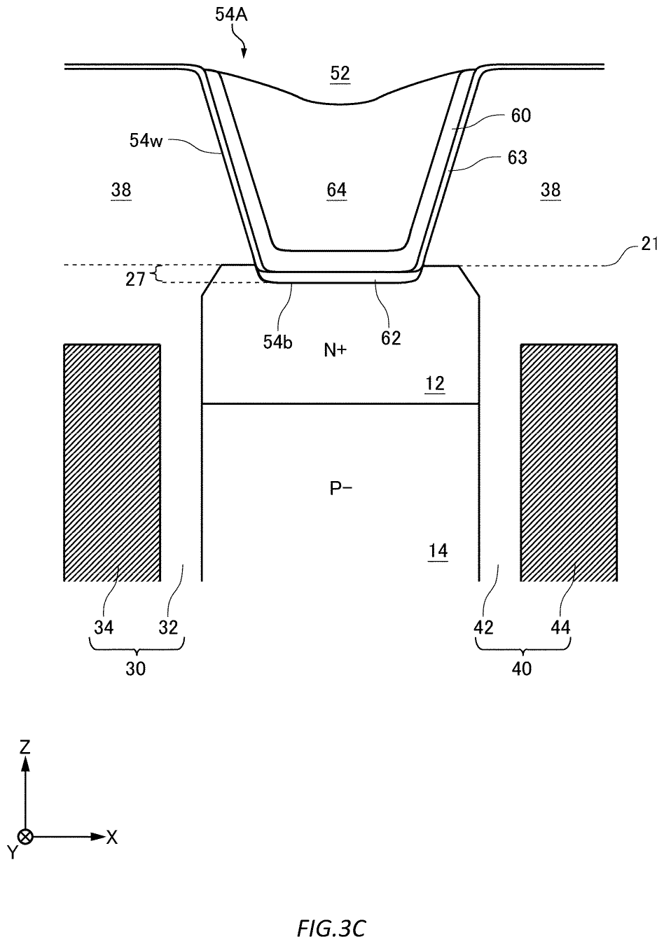

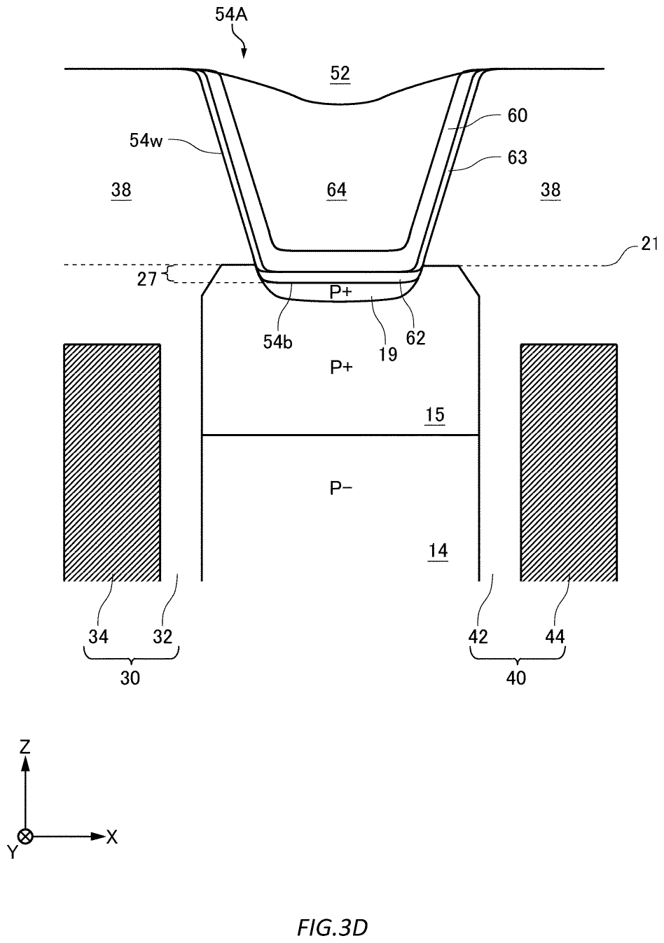

FIG. 3A is an enlarged view of a cross section of the semiconductor device 100. In the present example, an enlarged view of a cross section in the vicinity of the contact hole 54A is shown. The contact hole 54A is an example of the contact hole 54. The cross section of the present example is the XZ cross section which passes through the emitter region 12 at a front surface 21 of a semiconductor substrate 10. The contact hole 54A (contact hole 54) includes a bottom portion 54b and a side wall 54w. The contact hole 54A is provided with a first barrier metal layer 60, a first alloy layer 62, a second alloy layer 63, and a plug layer 64. The contact hole 54A is an example of the first contact hole.

Note that, for convenience in the present specification, of an inner wall of the contact hole 54, a region upper than the front surface 21 of the semiconductor substrate 10 is referred to as the side wall 54w and a region lower than the front surface 21 of the semiconductor substrate 10 is referred to as the bottom portion 54b. In addition, while the contact hole 54 is used to describe the structure in the vicinity of the contact hole in the present specification, the similar structure may be applied to other contact holes such as the contact hole 55 and the contact hole 56. That is, the first barrier metal layer 60, the first alloy layer 62, the second alloy layer 63, and the plug layer 64 may also be provided in other contact holes such as the contact hole 55 and the contact hole 56. The first alloy layer 62 is provided to cover the bottom portion 54b of the contact hole

54A. The first alloy layer 62 of the present example is an alloy layer formed as a result of reaction of polycrystalline. The first alloy layer 62 is provided to obtain a good contact. For example, the first alloy layer 62 is TiSi₂ formed by annealing an initial polycrystalline film of polysilicon and the first initial metal film of titanium (Ti) deposited on the bottom portion 54b of the contact hole 54A.

The second alloy layer 63 is provided to cover the side wall 54w of the contact hole 54A. The second alloy layer 63 of the present example is an alloy layer formed as a result of reaction of polycrystalline, similarly to the first alloy layer 62. For example, the second alloy layer 63 is TiSi₂ formed by annealing an initial polycrystalline film of polysilicon and a first initial metal film of titanium (Ti) deposited on the side wall 54w of the contact hole 54A. The first alloy layer 62 and the second alloy layer 63 may be formed by the same deposition and annealing processes.

The second alloy layer 63 may face the first alloy layer 62 at its lower end in a continuous manner. That is, an inner wall of the contact hole 54A may be covered by the first alloy layer 62 and the second alloy layer 63. Note that, in the drawings, the first alloy layer 62 and the second alloy layer 63 are shown so that they are clearly distinguished from each other merely for convenience. Among alloy layers formed in an integrated manner in the same process, a portion on the bottom portion 54b of the contact hole 54 may be referred to as a first alloy layer 62 and a portion on the side wall 54w may be referred to as a second alloy layer 63.

A thickness T of the second alloy layer 63 of the present example may be equal to or greater than 0.01 μm and equal to or smaller than 0.2 μm. Here, the thickness T of the second alloy layer 63 is a distance in a direction perpendicular to the side wall 54w of the contact hole 54A and may be a film thickness at the thickest position.

The first barrier metal layer 60 is provided inside the first alloy layer 62 and the second alloy layer 63 in the contact hole 54A. The first barrier metal layer 60 includes at least one of titanium (Ti), cobalt (Co), magnesium (Mg), vanadium (V), lanthanum (La), palladium (Pd), tantalum (Ta) or zirconium (Zr). The first barrier metal layer 60 of the present example is TiN formed as the second initial metal film by sputtering and processed in the annealing process. The first barrier metal layer 60 may be formed by the same annealing process as the first alloy layer 62 and the second alloy layer 63. In addition, the first barrier metal layer 60 may include a layer formed of a Ti film deposited as the first initial metal film and remaining as it has been and a layer nitrided in the annealing process.

The plug layer 64 is provided in contact with the first barrier metal layer 60 in the contact hole 54A. For example, the material of the plug layer 64 is tungsten. Use of tungsten having a good embeddability can miniaturize the device structure of the front surface. In addition, the first barrier metal layer 60 is provided to avoid erosion of the interlayer dielectric film 38, the first alloy layer 62 and the second alloy layer 63 due to a gas generated when depositing the plug layer 64.

The bottom portion 54b of the contact hole 54A may be provided at a position lower than the front surface 21 of the semiconductor substrate 10. That is, the semiconductor substrate 10 includes the recessed portion 27 provided in the emitter region 12 below the contact hole 54A and the first alloy layer 62 may be provided to be received in the recessed portion 27. The emitter region 12 is an example of the underlying layer provided on the front surface 21 of the semiconductor substrate 10 or above the semiconductor substrate 10. In this example, an upper surface of the underlying layer is positioned at the same height as the front surface 21. The upper surface of the underlying layer may be positioned at the same height as the front surface 21, may be at a position below the front surface 21, or may be positioned above the front surface 21. As an example of the upper surface of the underlying layer positioned below the front surface 21, as will be described below, the plug region 19 of the trench contact portion 65 of the mesa portion, the gate conductive portion 44, the dummy conductive portion 34 or the like may be applicable. As an example of the upper surface of the underlying layer positioned above the front surface 21, as will be described below, the connection portion 25 or the like, and in addition, a temperature sensing diode, a field plate of the edge termination structure portion 140 or the like may be applicable. The upper surface of the first alloy layer 62 may protrude from the recessed portion 27, that is, may be at a position upper than the front surface 21 of the semiconductor substrate 10.

The interlayer dielectric film 38 includes the contact hole 54A and is provided above the semiconductor substrate 10. Although the interlayer dielectric film 38 includes one layer of a dielectric film provided above the front surface 21, the interlayer dielectric film 38 may alternatively include a plurality of stacked dielectric films. The interlayer dielectric film 38 may be a silicon oxide film such as BPSG.

Here, when electron beams, particle beams, and the like for forming the lifetime control region pass through the MOS gate structure, a defect may be generated in the vicinity of an interface between the oxide film and the semiconductor layer in the MOS gate structure. Then, when metal such as Ti having a hydrogen absorbing effect exists in the vicinity of the MOS gate structure, hydrogen diffused in the gate portion may be absorbed so as to result in an inhibition of a hydrogen termination of a dangling bond of the MOS gate structure and a variation of a threshold voltage. Conventionally, a silicide layer provided on a bottom portion of a contact hole is formed of a first initial metal film of Ti or the like bonded with silicon of a semiconductor substrate. Therefore, an unreacted first initial metal film having a hydrogen absorbing effect may remain on an upper surface and a lower surface side of the silicide layer. In addition, an element of the semiconductor substrate reacting with the first initial metal film does not exist on a side surface of the contact hole. Therefore, an unreacted first initial metal film may remain on an upper surface and a lower surface side of the silicide layer.

According to the semiconductor device 100 of the present example, the initial polycrystalline film deposited to form the first alloy layer 62 and the second alloy layer 63 is bonded with the first initial metal film to prevent the first initial metal film having a hydrogen absorbing effect from remaining or to reduce the remaining amount. Thus, the influence of the hydrogen absorbing effect can be suppressed and the hydrogen termination of dangling bonds of the MOS gate structure can be facilitated. Accordingly, a variation of a threshold voltage can be suppressed.

It is to be noted that although an influence of the electron beams and particle beams for forming the lifetime control region on the MOS gate structure becomes large when irradiating the beams from the front surface 21 side of the semiconductor substrate 10, the beams may affect the MOS gate structure also when being irradiated from the back surface 23 side of the semiconductor substrate 10. Thus, also when irradiating from the back surface 23 side, the semiconductor device 100 can recover the damage of the MOS gate structure and suppress the variation of the threshold voltage. It is to be noted that although an acceleration voltage becomes large to result in an increase in the size of the device when irradiating particle beams and the like from the back surface 23 side of the semiconductor substrate 10, in the semiconductor device 100 of the present example, the influence of irradiating particle beams and the like from the front surface 21 can be suppressed, and thus the lifetime control region can be formed with a more compact device.

Note that the first initial metal film may remain on an upper surface or a lower surface of the second alloy layer 63 as it has been without entirely reacting with the initial polycrystalline film or in a state of a product as a result of reaction with an atmosphere in the annealing process or may configure a part of the first barrier metal layer 60. If the first initial metal film is deposited on the initial polycrystalline film, the first initial metal film may remain on the upper surface of the second alloy layer 63. If the initial polycrystalline film is deposited on the first initial metal film, the first initial metal film may remain on the lower surface of the second alloy layer 63. This is also true with respect to the bottom portion 54b of the contact hole 54A. In this manner, even if the first initial metal film remains, the initial polycrystalline film is bonded with the first initial metal film to decrease the first initial metal film having a hydrogen absorbing effect and suppress the variation of the threshold voltage.

If the first initial metal film remains on the upper surface of the second alloy layer 63, or if the first initial metal film remains on the upper surface of the first alloy layer 62, the enlarged view of the cross section of the semiconductor device 100 passing through the emitter region 12 will be as shown in FIG. 3A and a layer derived from the first initial metal film may be stacked with a layer derived from the second initial metal film to form a part of the first barrier metal layer 60.

On the other hand, if the first initial metal film remains on the lower surface of the second alloy layer 63, the enlarged view of the cross section of the semiconductor device 100 passing through the emitter region 12 will be as shown in FIG. 3B. On the side wall 54w of the contact hole, the first barrier metal layer 60 derived from the second initial metal film, the second alloy layer 63 formed as a result of reaction of the initial polycrystalline film and the first initial metal film, and the first barrier metal layer 60 derived from the first initial metal film are formed in the order from the upper surface side. Similarly, on the bottom portion 54b of the contact hole, the first barrier metal layer 60 derived from the second initial metal film, the first alloy layer 62 formed as a result of reaction of the initial polycrystalline film and the first initial metal film, the first barrier metal layer 60 derived from the first initial metal film, and the first alloy layer 62 formed as a result of reaction of silicon of the mesa portion 71 and the first initial metal film may be formed in the order from the upper surface side. The stacking structure may be formed on either of the side wall 54w or the bottom portion 54b of the contact hole or on both of them.

In the first barrier metal layer 60 in the examples shown in FIG. 3B and the subsequent figures, similarly to FIG. 3B, a layer derived from the first initial metal film may also be formed on the lower surface of the second alloy layer 63 on the side wall 54w of the contact hole or, as will be described below, on the upper surface of the interlayer dielectric film 38. In addition, on the bottom portion 54b of the contact hole, the first barrier metal layer 60 and the first alloy layer 62 or a third alloy layer 68 which will be described below may form a layer with each other.

In addition, the second alloy layer 63 may also be formed on the upper surface of the interlayer dielectric film 38 outside the contact hole 54A, as shown in FIG. 3C. The second alloy layer 63 of the upper surface of the interlayer dielectric film 38 may be formed with the second alloy layer 63 deposited on the side wall 54w of the contact hole 54A in an integrated manner. On the upper surface of the interlayer dielectric film 38 outside the contact hole 54A, the first barrier metal layer 60 may not be formed on the upper surface of the second alloy layer 63. After being formed with the first barrier metal layer 60 deposited on the upper surface of the second alloy layer 63 on the side wall 54w of the contact hole 54A in an integrated manner, only a portion of the first barrier metal layer 60 on the upper surface of the interlayer dielectric film 38 is etched back to form the contact hole 54A shown in the present example. In the example shown in FIG. 3C and the subsequent figures, in the example described for the second alloy layer 63 not formed on the upper surface of the interlayer dielectric film 38 outside the contact hole, the second alloy layer 63 may also be formed on the upper surface of the interlayer dielectric film 38, similarly to the present example.

FIG. 3D is an enlarged view of a cross section of the semiconductor device 100. The cross section of the present example passes through the contact region 15 on the front surface 21 of the semiconductor substrate 10, unlike the cross section of FIG. 3A. In this example, difference with FIG. 3A will be particularly described.

A plug region 19 of the P+ type having a doping concentration higher than that of the contact region 15 may be provided below the contact hole 54A. The plug region 19 is an example of the underlying layer provided on the front surface 21 of the semiconductor substrate 10 or above the semiconductor substrate 10. The plug region 19 may be provided in a region below the contact hole 54A and above the contact region 15. A lower end of the plug region 19 may be provided to be shallower than a lower end of the contact region 15. Via the contact hole 54A, holes are extracted from the contact region 15 and the plug region 19. The plug region 19 improves the contact resistance between the first barrier metal layer 60 of the contact hole 54A and the contact region 15 to improve the latch up withstand capability.

The plug region 19 may be provided in a region below the contact hole 54A and above the base region 14. The plug region 19 may be provided in the mesa portion 71 and the mesa portion 91. The plug region 19 may not be provided in a region below the contact hole 54A and above the emitter region 12. In this case, the plug regions 19 may be provided discretely along the contact hole 54A to correspond to the repeated structure of the emitter regions 12 and the contact regions 15 in the mesa portion 71 and the mesa portion 91.

If the mesa portion 81 is provided with the contact hole 54A, the plug region 19 is provided below the contact hole 54A. This improves the contact resistance between the base region 14 and the first alloy layer 62. Note that the plug region 19 may not be provided in the entire region of the contact region 15 and the base region 14, and may be provided partially or discretely. In a region where the plug region 19 is not formed, the contact region 15 or the base region 14 may be an example of the underlying layer provided on the front surface 21 of the semiconductor substrate 10 or above the semiconductor substrate 10. This suppresses hole injection from the region where the plug region 19 is not formed into the semiconductor substrate 10 when the diode portion 80 is in conduction. If the contact hole 54A is provided in the mesa portion 81, the second alloy layer 63 is provided on the side wall 54w of the contact hole and the first alloy layer 62 is provided on the bottom portion 54b thereof such that a Ti layer included in the first barrier metal layer 60 is removed or decreased to suppress the variation of the threshold of the mesa portion 71 and the mesa portion 91.

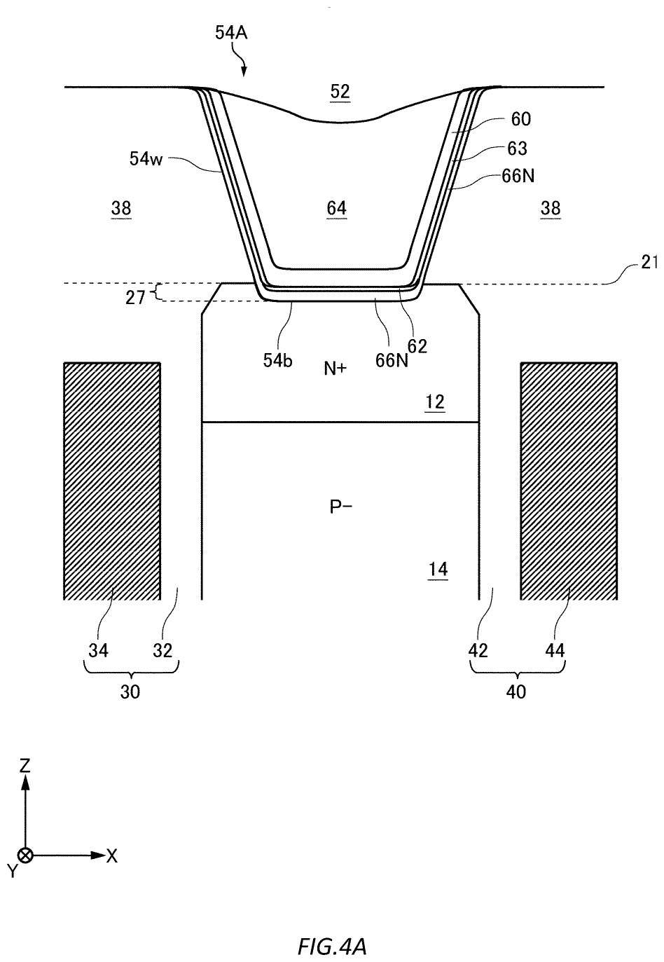

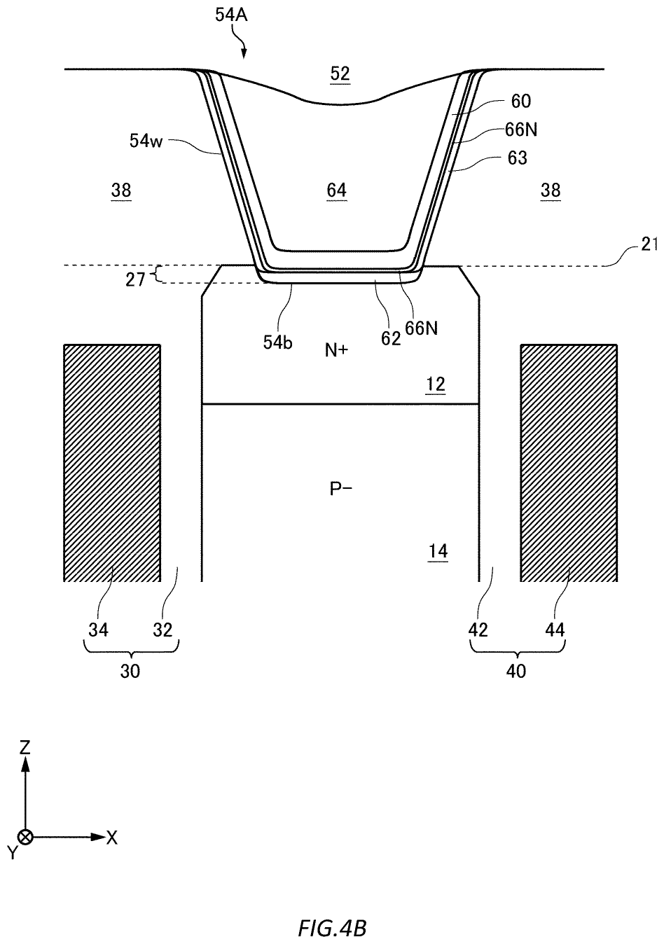

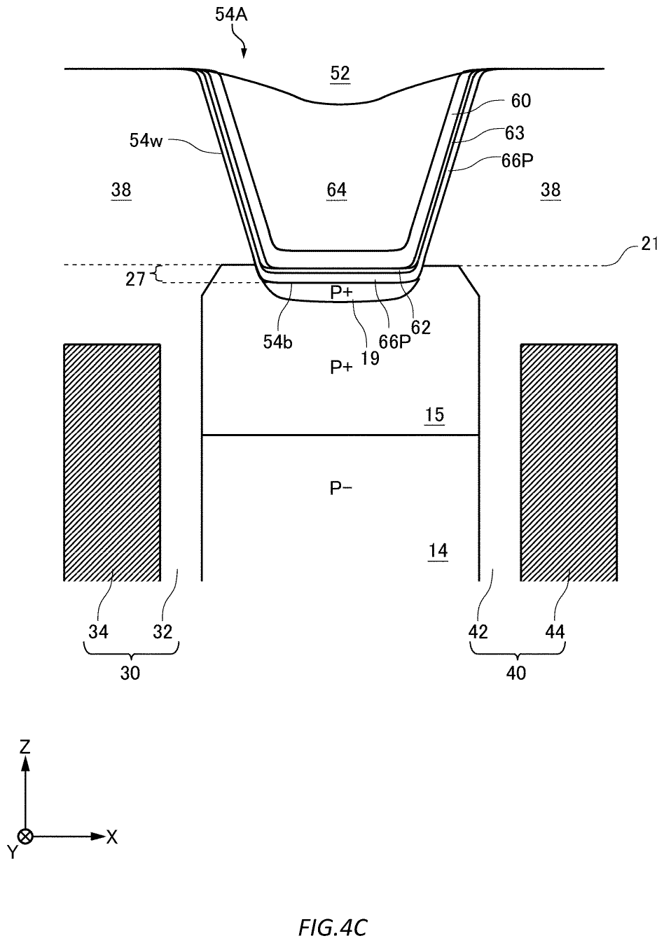

FIG. 4A is an enlarged view of a cross section of the semiconductor device 100. In the present example, an enlarged view of a cross section in the vicinity of the contact hole 54A is shown. The cross section in the present example is the XZ cross section which passes through the emitter region 12 at a front surface 21 of a semiconductor substrate 10. The present example is different from the example of FIG. 3A in an impurity-implanted polycrystalline layer 66 provided on a lower surface of the second alloy layer 63 in the contact hole 54A.

The impurity-implanted polycrystalline layer 66 of the present example is provided on a lower surface of the first alloy layer 62, that is, to be interposed between the bottom portion 54b and the first alloy layer 62. The impurity-implanted polycrystalline layer 66 is also provided on a lower surface of the second alloy layer 63, that is, between the side wall 54w and the second alloy layer 63. If the second alloy layer 63 is also formed on the upper surface of the interlayer dielectric film 38, the impurity-implanted polycrystalline layer 66 may be provided on the upper surface of the interlayer dielectric film 38 and on the lower surface of the second alloy layer 63.

The impurity-implanted polycrystalline layer 66 may be provided on the lower surface of the first alloy layer 62 and may not be provided on the lower surface of the second alloy layer 63. The impurity-implanted polycrystalline layer 66 may not be provided on the lower surface of the first alloy layer 62 and may be provided on the lower surface of the second alloy layer 63. The impurity-implanted polycrystalline layer 66 may also be provided on the lower surfaces of the first alloy layer 62 and the second alloy layer 63 in part.

The impurity-implanted polycrystalline layer 66 is formed by introducing impurities into the remaining initial polycrystalline film when the initial polycrystalline film deposited to form the first alloy layer 62 and the second alloy layer 63 remains without being bonded with the first initial metal film. Impurities may be doped when depositing the film or may be introduced by ion implantation after depositing the film. The impurity-implanted polycrystalline layer 66N is an example of the impurity-implanted polycrystalline layer 66. The impurity-implanted polycrystalline layer 66N provided above the emitter region 12 is of the N type.

FIG. 4B is an enlarged view of the cross section of the semiconductor device 100. In the present example, an enlarged view of a cross section in the vicinity of the contact hole 54A is shown. The cross section in the present example is the XZ cross section which passes through the emitter region 12 at a front surface 21 of a semiconductor substrate 10. The present example is different from the example of FIG. 4A in an impurity-implanted polycrystalline layer 66N provided on an upper surface of the second alloy layer 63 in the contact hole 54A.

The impurity-implanted polycrystalline layer 66N of the present example is provided on the upper surface of the first alloy layer 62, that is, to be interposed between the first barrier metal layer 60 and the first alloy layer 62. The impurity-implanted polycrystalline layer 66N is also provided on the upper surface of the second alloy layer 63, that is, between the first barrier metal layer 60 and the second alloy layer 63.

The impurity-implanted polycrystalline layer 66N is provided on upper surfaces of the first alloy layer 62 and the second alloy layer 63. The impurity-implanted polycrystalline layer 66N may be provided on the upper surface of the first alloy layer 62 and may not be provided on the upper surface of the second alloy layer 63. The impurity-implanted polycrystalline layer 66N may not be provided on the upper surface of the first alloy layer 62 and may be provided on the upper surface of the second alloy layer 63. The impurity-implanted polycrystalline layer 66N may also be provided on the upper surfaces of the first alloy layer 62 and the second alloy layer 63 in part.

FIG. 4C is an enlarged view of a cross section of the semiconductor device 100. The cross section of the present example passes through the contact region 15 on the front surface 21, unlike the cross section of FIG. 4A. The impurity-implanted polycrystalline layer 66P is an example of the impurity-implanted polycrystalline layer 66. The impurity-implanted polycrystalline layer 66P provided above the contact region 15 is of the P type.

In this manner, the impurity-implanted polycrystalline layer 66 is provided on the lower surface of the first alloy layer 62 to suppress an increase in the resistance due to the remaining initial polycrystalline film such that movement of electric charges is not suppressed. While the impurity-implanted polycrystalline layer 66 is provided on the entire lower or upper surface sides of both of the first alloy layer 62 and the second alloy layer 63 in FIG. 4A, FIG. 4B, and FIG. 4C, it may be provided on any one of the lower surface or the upper surface or may be provided in part. The polarity of the impurity-implanted polycrystalline layer 66 on the lower surface of the first alloy layer 62 needs to be identical to the polarity of the emitter region 12 or the contact region 15 or the plug region 19 at least in part in a region in contact with these regions, and may not be identical to the polarity of the impurity-implanted polycrystalline layer 66 on the lower surface of the second alloy layer 63. In addition, even if the initial polycrystalline film remains on the lower surface of the second alloy layer 63, impurities do not need to be introduced.

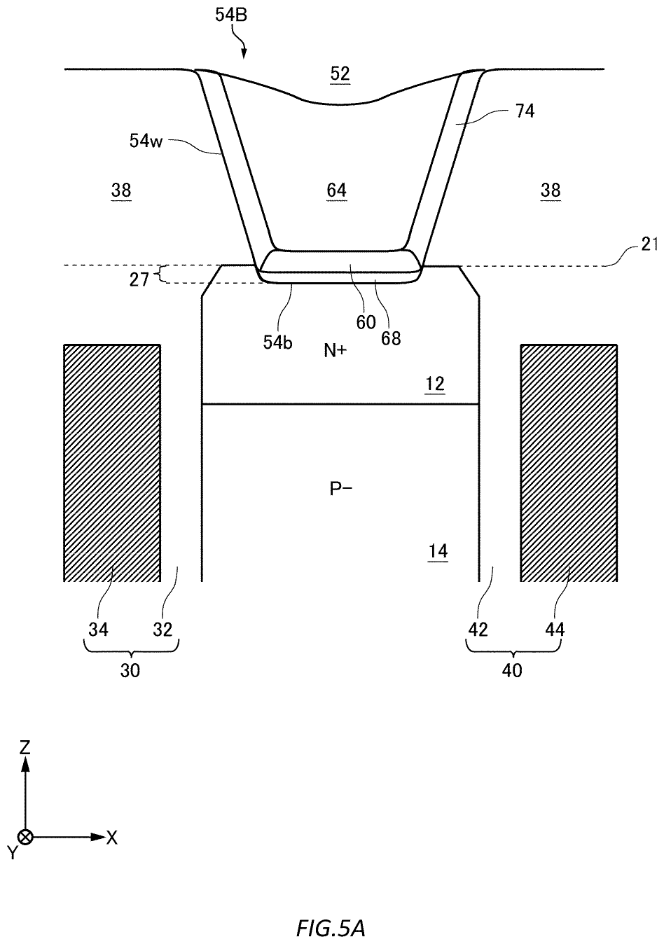

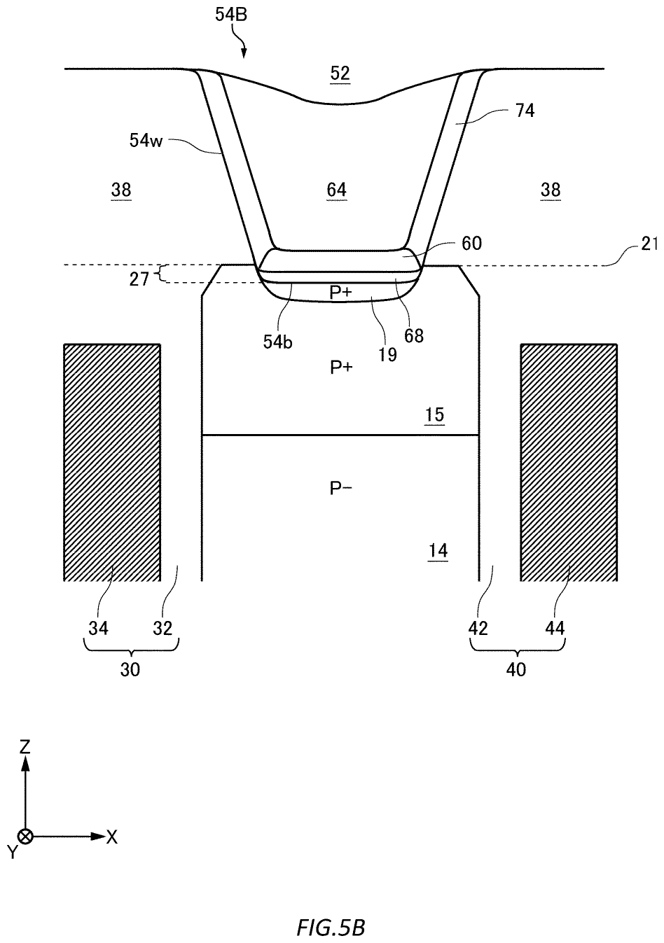

FIG. 5A is an enlarged view of a cross section of the semiconductor device 100. In the present example, an enlarged view of a cross section in the vicinity of the contact hole 54B is shown. The cross section in the present example is the XZ cross section which passes through the emitter region 12 at a front surface 21 of a semiconductor substrate 10. The contact hole 54B is an example of the contact hole 54. In the present example, a difference from the contact holes 54A of FIG. 3A to FIG. 4C will be described in particular.

In the contact hole 54B, a third alloy layer 68 is provided on the bottom portion 54b, the second barrier metal layer 74 is provided on the side wall 54w, and the first barrier metal layer 60 is provided on the third alloy layer 68. The third alloy layer 68 is not provided on the side wall 54w of the contact hole 54B. That is, the contact hole 54B is provided with the third alloy layer 68, instead of the first alloy layer 62 of the contact hole 54A, and is not provided with the second alloy layer 63. The contact hole 54B is an example of the second contact hole.

The third alloy layer 68 is formed by annealing a first initial metal film such as Ti. In the present example, the third alloy layer 68 is formed as a result of reaction of the emitter region 12 which is an example of the underlying layer and the first initial metal film. The third alloy layer 68 of the present example is TiSi₂ formed of Ti deposited on the bottom portion 54b of the contact hole 54B as the first initial metal film bonded with silicon of the semiconductor substrate 10.

The second barrier metal layer 74 of the present example may be a stacking structure where a TiN film is formed by sputtering as the second initial metal film on a Ti film of the first initial metal film deposited on the side wall 54w of the contact hole 54B as the first initial metal film. In addition, a TiN film formed by annealing Ti of the first initial metal film in the nitrogen atmosphere may be included. In the contact hole 54B, in particular, it may be highly possible that an unreacted first initial metal film having a hydrogen absorbing effect remains on the side wall 54w. Accordingly, the contact hole 54B may be provided in a region, range, and degree such that the remaining unreacted first initial metal film does not affect the threshold voltage.

FIG. 5B is an enlarged view of the cross section of the semiconductor device 100. In the present example, an enlarged view of a cross section in the vicinity of the contact hole 54B is shown. The cross section of the present example passes through the contact region 15 on the front surface 21 of the semiconductor substrate 10, unlike the cross section of FIG. 5A. In the present example, a difference from FIG. 5A will be particularly described.

Like the contact holes 54A of FIG. 3D and FIG. 4C, the plug region 19 of the P+ type having a doping concentration higher than that of the contact region 15 may be provided below the contact hole 54B. In the present example, the plug region 19 which is an example of the underlying layer and the first initial metal film react to form the third alloy layer 68.

In the diode portion 80, the mesa portion 81 where the plug region 19 is formed may be provided with the contact hole 54B. As described above, the contact hole 54B is provided with the third alloy layer 68, instead of the first alloy layer 62 and the second alloy layer 63 which are polycrystalline layers. In the contact hole 54B where an initial polycrystalline film is not deposited to form a polycrystalline layer, titanium only reacts with silicon of the mesa portion 81 so that the third alloy layer 68 is formed. Therefore, the plug region 19 of the P+ type having a higher doping concentration decreases as compared to the case where the first alloy layer 62 is formed of titanium reacting with the initial polycrystalline film. Therefore, the contact hole 54B is provided in the mesa portion 81 where the plug region 19 is formed such that hole injection from the plug region 19 can be suppressed. Note that, in a region where the plug region 19 is not provided, the contact region 15 and the base region 14 which are an example of the underlying layer and the first initial metal film react to form the third alloy layer 68.

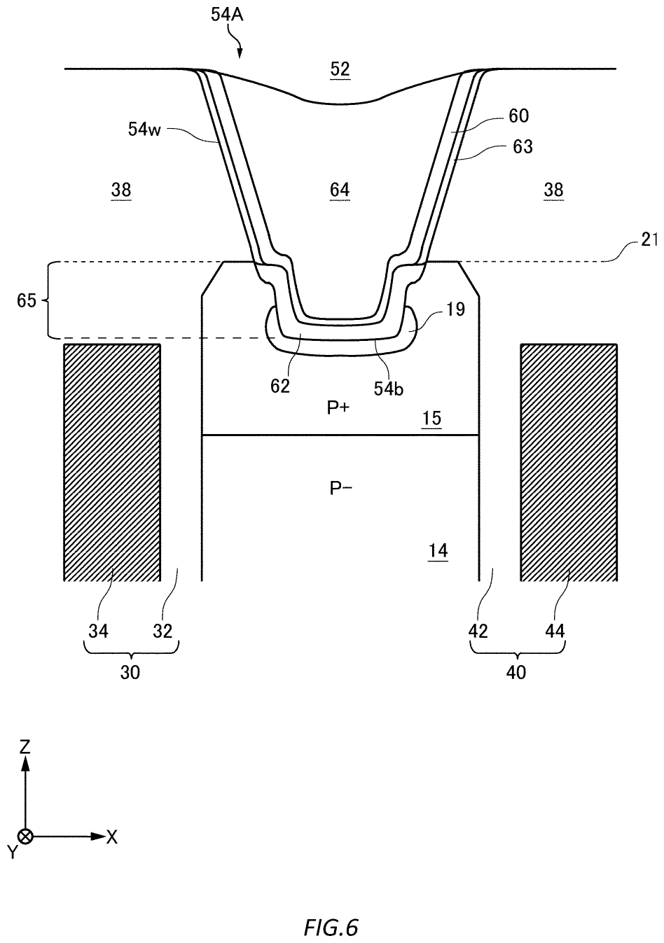

FIG. 6 is an enlarged view of a cross section of the semiconductor device 100. In the

present example, an enlarged view of a cross section in the vicinity of the contact hole 54A is shown. The cross section of the present example is an XZ cross section passing through the contact region 15 on the front surface 21 of the semiconductor substrate 10. In the present example, a difference from the contact holes 54A of FIG. 3A to FIG. 4C will be described in particular.

The contact hole 54A of the present example includes a trench contact portion 65 provided to extend in the depth direction from the front surface 21 of the semiconductor substrate 10. That is, the contact hole 54A includes a region extending from an upper surface of the interlayer dielectric film 38 to the front surface 21 of the semiconductor substrate 10 and a region extending in the depth direction from the front surface 21 of the semiconductor substrate 10 (the trench contact portion 65). The bottom portion 54b of the contact hole 54A is a lower end of the trench contact portion 65, the side wall 54w of the contact hole 54A is a region of the inner wall of the contact hole 54A ranging from the upper surface of the interlayer dielectric film 38 to the front surface 21 of the semiconductor substrate 10, and the bottom portion 54b is an inner wall of the trench contact portion 65.

The lower end of the trench contact portion 65 of the present example is shallower than the lower end of the contact region 15. The lower end of the trench contact portion 65 may be deeper than the lower end of the contact region 15. The lower end of the trench contact portion 65 of the present example is shallower than the upper end of the gate conductive portion 44. The lower end of the trench contact portion 65 may be deeper than the upper end of the gate conductive portion 44.

In this manner, the semiconductor device 100 of the present example is provided with the contact hole 54A including the trench contact portion 65 to increase an area contacting the semiconductor substrate 10 such that the contact resistance can be reduced, and a distance from the base region 14 to the plug layer 64 is shortened to enable a lower resistance for a hole current. The contact hole 54A is provided in the transistor portion 70 to facilitate to extract holes such that latch up can be suppressed.

Note that a cross section where the contact hole 54A passes through the emitter region 12 is the same as FIG. 3A illustrating the contact hole 54A, except for the trench contact portion 65, and thus the illustration thereof is omitted. The lower end of the trench contact portion 65 of the present example is shallower than the lower end of the emitter region 12. The lower end of the trench contact portion 65 may be deeper than the lower end of the emitter region 12. The lower end of the trench contact portion 65 of the present example is shallower than the upper end of the gate conductive portion 44. The lower end of the trench contact portion 65 may be deeper than the upper end of the gate conductive portion 44. At the lower end of the trench contact portion 65, the plug region 19 common with the contact region 15 may be provided. In addition, the structure including the trench contact portion 65 may be applied to the contact hole 54B.

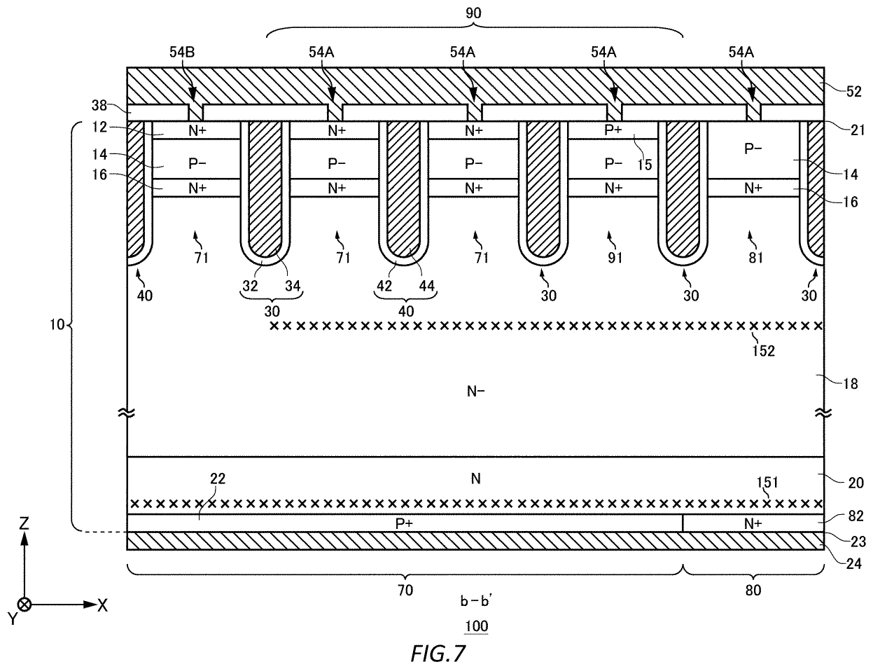

FIG. 7 shows an example of a b-b′ cross section in FIG. 2B. The semiconductor device 100 of the present example includes the transistor portion 70 and a diode portion 80. In addition, the semiconductor device 100 of the present example includes a back surface side lifetime control region 151 and a front surface side lifetime control region 152.

In the semiconductor device 100 of the present example, the contact holes 54 provided in the main region of the transistor portion 70 are the contact holes 54B shown in FIG. 5A and FIG. 5B and the contact holes 54 provided in the diode portion 80 and the boundary region 90 are the contact holes 54A shown in FIG. 3A and FIG. 3D. The contact hole 54A may be those shown in FIG. 4A to FIG. 4C (including the impurity-implanted polycrystalline layer 66). In addition, the contact hole 54A and the contact hole 54B may be provided with the trench contact portion 65, as shown in FIG. 6.

That is, the semiconductor device 100 of the present example is provided with the contact holes 54A only in the diode portion 80 and the boundary region 90 where the front surface side lifetime control region 152 is provided. This can replace the unreacted first initial metal film having a hydrogen absorbing effect with the first alloy layer and the second alloy layer in the region through which an electron beam and a particle beam pass to form the front surface side lifetime control region 152 to suppress the variation of the threshold voltage due to the influence of the hydrogen absorbing effect. In addition, the plug region 19 of the P+ type having a higher doping concentration remains in the boundary region 90 to facilitate to extract holes even when the current crowding occurs when turned off such that a decrease in the threshold can be negated even if it is not completely suppressed.

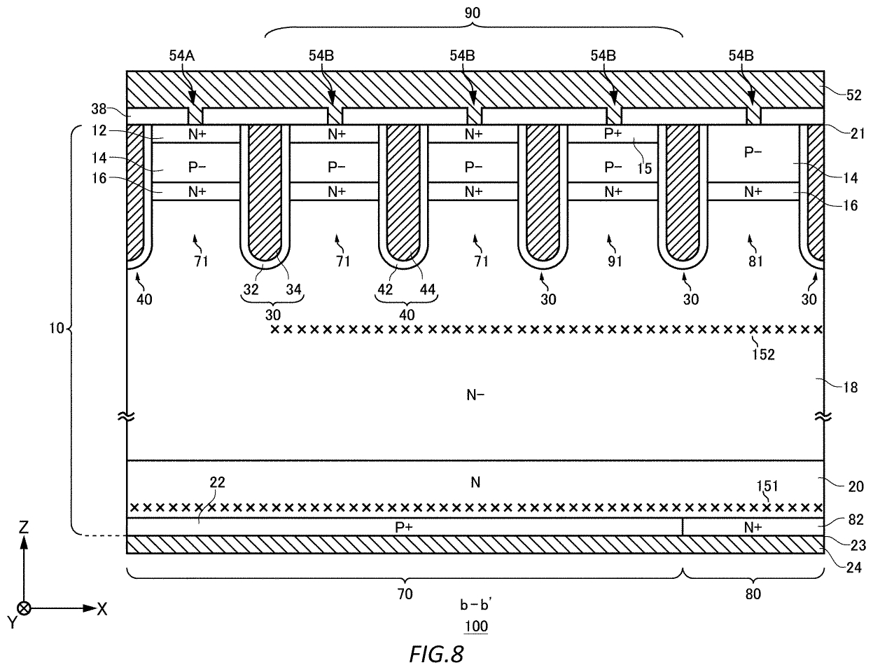

FIG. 8 shows another example of a b-b′ cross section in FIG. 2B. In the present example, a difference from FIG. 7 will be particularly described.

In the semiconductor device 100 of the present example, the contact holes 54 provided in the main region of the transistor portion 70 are the contact holes 54A shown in FIG. 3A and FIG. 3D and the contact holes 54 provided in the diode portion 80 and the boundary region 90 are contact holes 54B shown in FIG. 5A and FIG. 5B.

That is, the semiconductor device 100 of the present example is provided with the contact holes 54A only in the main region of the transistor portion 70 where the front surface side lifetime control region 152 is not provided. If an area of the diode portion 80 and the boundary region 90 where the front surface side lifetime control region 152 is provided is larger than an area of the main region of the transistor portion 70 not provided with the front surface side lifetime control region 152, the unreacted first initial metal film having a hydrogen absorbing effect can be replaced with the first alloy layer and the second alloy layer in the main region of the transistor portion 70 of a higher area ratio in this manner to suppress the variation of the threshold voltage due to the influence of the hydrogen absorbing effect.

In addition, in the main region of the transistor portion 70, the initial polycrystalline film is deposited on the bottom portion 54b of the contact hole 54A so that titanium is not bonded with silicon of the mesa portion 71 and the plug region 19 of the P+ type having a higher doping concentration remains. Therefore, the front surface side lifetime control region 152 is not provided so that holes tend to accumulate. However, holes are extracted when turned off such that latch up can be suppressed. On the other hand, in the boundary region 90, titanium is bonded with silicon of the mesa portion 91 so that the plug region 19 of the P+ type having a higher doping concentration decreases. Therefore, hole injection from the plug region 19 and the contact region 15 of the mesa portion 91 can be suppressed during the diode operation.

Note that, in FIGS. 7 and 8, the boundary region 90 and the diode portion 80 include the same contact holes and the main region of the transistor portion 70 includes the different contact hole, in accordance with the boundary of the front surface side lifetime control region 152, but they are not limited thereto. It may be selected as appropriate how and which one of the contact hole 54A or 54B is provided in each region to suppress a decrease in the threshold voltage by reducing an amount of the unreacted first initial metal film having a hydrogen absorbing effect and adjust the concentration of holes of the mesa portion in a good balance. The boundary of the front surface side lifetime control region 152 may not align with a switching point between the contact hole 54A and the contact hole 54B. If the front surface side lifetime control region 152 is provided in the entire region of the semiconductor device, if not provided in the entire region, or provided in a plurality of regions separately, the contact hole 54A and the contact hole 54B may be provided in the transistor portion 70 and the diode portion 80 as appropriate.

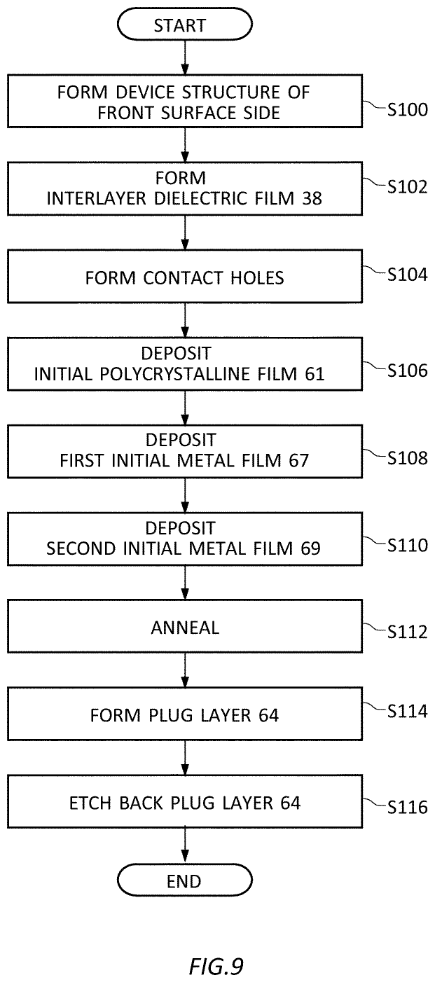

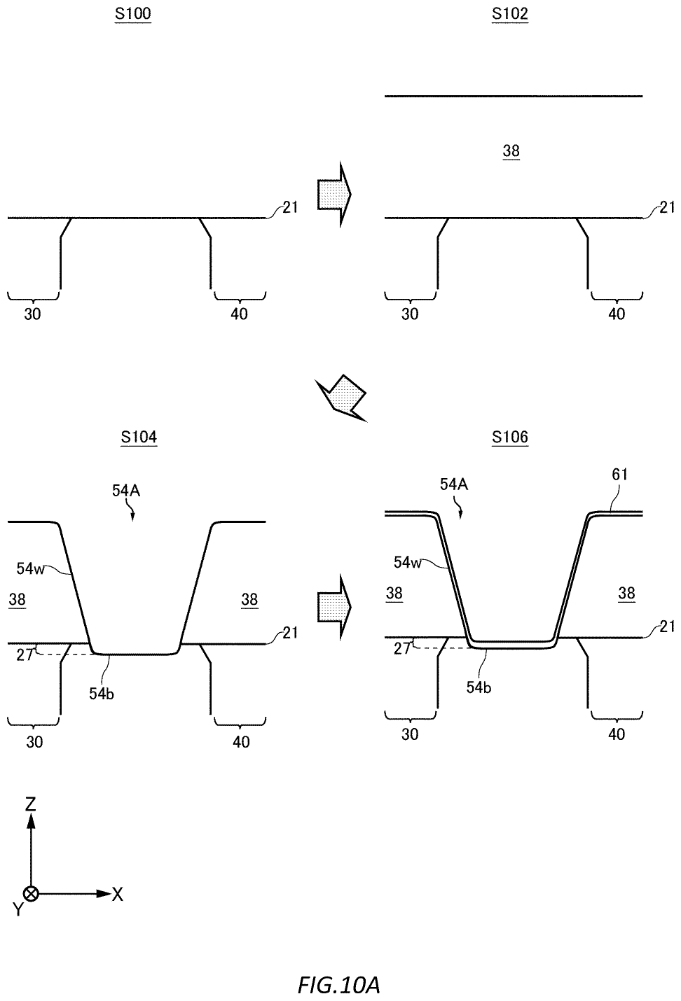

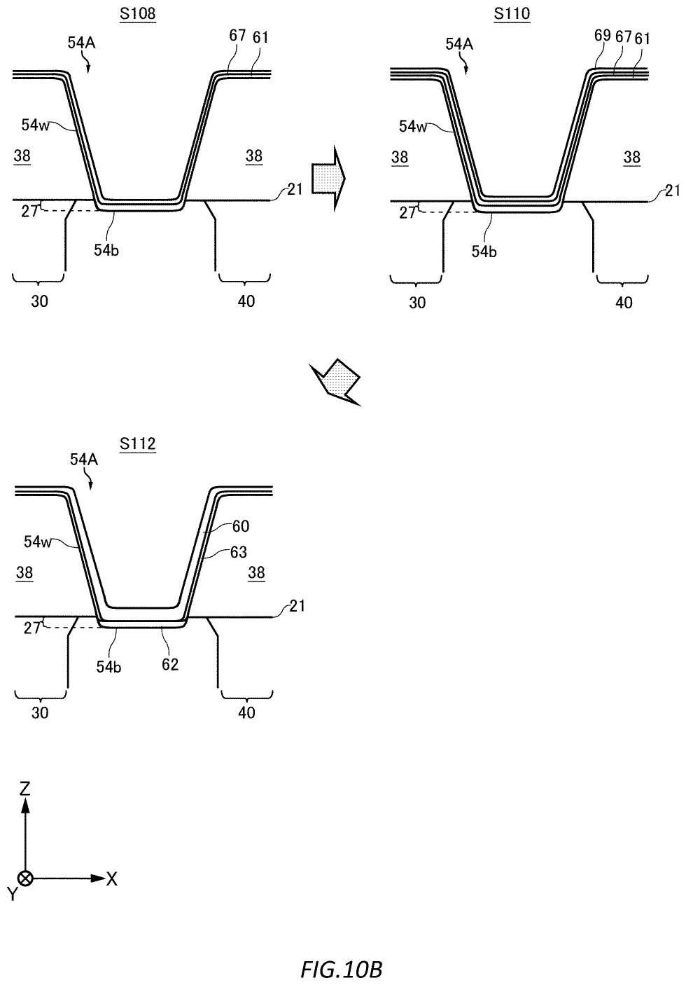

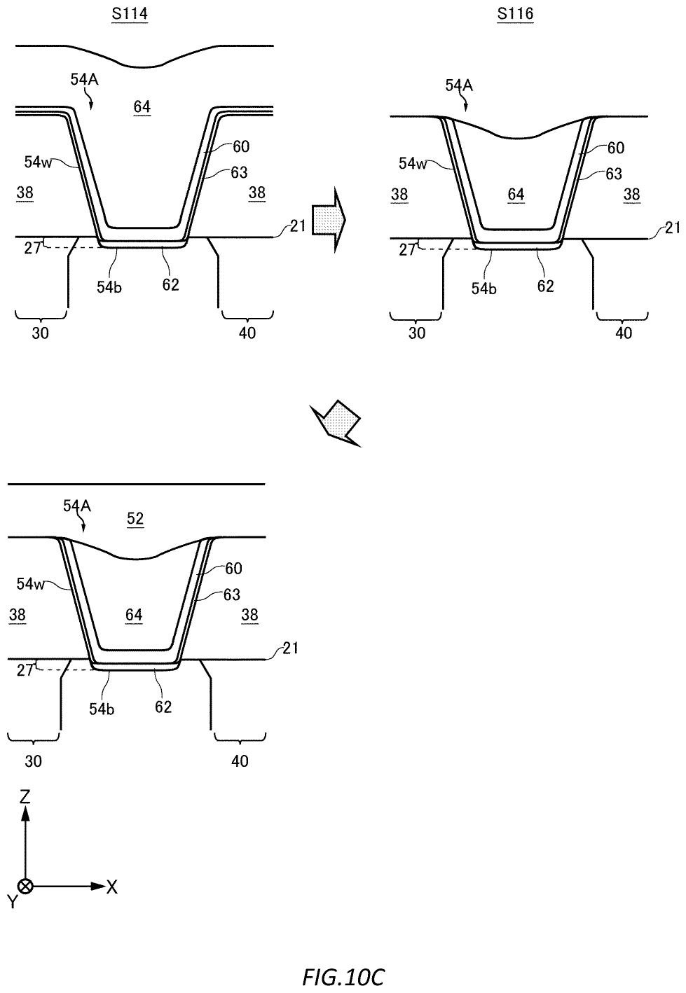

FIG. 9 is a flowchart showing an example of a manufacturing process of the semiconductor device 100. FIG. 10A to FIG. 10C are diagrams showing an example of a manufacturing process of the semiconductor device 100. Here, an example of the manufacturing process of the semiconductor device 100 will be described with reference to each process shown in FIG. 10A to FIG. 10C as appropriate.

In the step S100, a device structure of the front surface 21 side of the semiconductor substrate 10 is formed. The step S100 may include a process of forming the dummy trench portion 30 and the gate trench portion 40 as the device structure on the front surface 21 side. The step S100 may include a process of forming the base region 14, the emitter region 12 and the contact region 15 or the like as the device structure of the front surface 21 side by ion implantation into the semiconductor substrate 10.

In the step S102, the interlayer dielectric film 38 is formed above the front surface 21 of the semiconductor substrate 10. The interlayer dielectric film 38 may be a silicon oxide film such as BPSG. The interlayer dielectric film 38 may be formed by stacking a plurality of dielectric films.

In the step S104, the contact hole is formed by etching the interlayer dielectric film 38. Here, the recessed portion 27 is formed by over-etching the front surface 21 of the semiconductor substrate 10. In other words, the contact hole 54 having a sufficient dimension can be formed by keeping etching after reaching the front surface 21 of the semiconductor substrate 10 until the recessed portion 27 is formed. The trench contact portion 65 may further be formed. In addition, the plug region 19 may be formed between the step S104 and the step S106.

In the step S104, contact holes such as the contact hole 54, the contact hole 55, and the contact hole 56 may be formed in the interlayer dielectric film 38. Here, the contact holes 54A shown in FIG. 3A and FIG. 3D are described as an example of the contact hole 54.

In the step S106, an initial polycrystalline film 61 is deposited to cover the bottom portion 54b and the side wall 54w of the contact hole 54A. The initial polycrystalline film 61 may also be deposited on the upper surface of the interlayer dielectric film 38. On the bottom portion 54b of the contact hole 54A, the initial polycrystalline film 61 may be formed in the recessed portion 27. That is, an upper surface of the initial polycrystalline film 61 deposited on the bottom portion 54b of the contact hole 54A may be lower than the front surface 21 of the semiconductor substrate 10. Preferably, the initial polycrystalline film 61 is deposited after the step S110 which will be described below to have a film thickness such that the first initial metal film 67 does not remain on the side wall 54w of the contact hole 54A.

In the step S108, in the contact hole 54A, an first initial metal film 67 is deposited on the initial polycrystalline film 61. The first initial metal film 67 may also be deposited above the interlayer dielectric film 38. For example, the first initial metal film 67 is a Ti film deposited by sputtering. Note that, the order of the step 106 and the step S108 may be switched such that the initial polycrystalline film 61 is deposited on the first initial metal film 67.

In the step S110, the second initial metal film 69 is formed on the first initial metal film 67. The second initial metal film 69 may also be deposited on the upper surface of the interlayer dielectric film 38. For example, the second initial metal film 69 is a TiN film deposited by sputtering. The second initial metal film 69 may be deposited continuously by the same device as that of the first initial metal film 67 in the step S108.

In the step S112, the semiconductor substrate 10 is annealed in a nitrogen atmosphere.

This causes reaction of the initial polycrystalline film 61 and the first initial metal film 67 to form the first alloy layer 62 on the bottom portion 54b of the contact hole 54A and form the first barrier metal layer 60 in contact with the upper surface of the first alloy layer 62. The second alloy layer 63 is formed on the side wall 54w of the contact hole 54A and the upper surface of the interlayer dielectric film 38, and the first barrier metal layer 60 is formed in contact with the upper surface of the second alloy layer 63. The first alloy layer 62 and the second alloy layer 63 of the present example are TiSi₂ formed of the Ti first initial metal film 67 reacting with the polysilicon initial polycrystalline film 61 to be silicided.

Ti of the first initial metal film 67 is bonded with the initial polycrystalline film 61 and replaced with the first alloy layer 62 and second alloy layer 63. A thickness T of the second alloy layer 63 may be equal to or greater than 0.01 μm and equal to or smaller than 0.2 μm. Note that a part of the first initial metal film 67 may be bonded with the semiconductor substrate 10 to form the first alloy layer 62.

Note that, after the step S112, an unreacted polycrystalline film may remain on the side wall 54w of the contact hole 54A in particular. Therefore, impurities may be implanted after the step S106, and/or the initial polycrystalline film 61 may be deposited while impurities are introduced into the initial polycrystalline film 61 in the step S106 such that the impurity-implanted polycrystalline layer 66 shown in FIG. 4A to FIG. 4C is formed between the first alloy layer 62 and the bottom portion 54b and between the second alloy layer 63 and the side wall 54w.

The first barrier metal layer 60 may be the second initial metal film 69. In addition, by

annealing in the step S112, the first initial metal film 67 not bonded with the initial polycrystalline film 61 on the bottom portion 54b and the side wall 54w of the contact hole 54A and on the upper surface of the interlayer dielectric film 38 may be nitrided to form a TiN film configuring a part of the first barrier metal layer 60. In addition, a part of the first initial metal film 67 deposited on the bottom portion 54b and the side wall 54w of the contact hole 54A and on the upper surface of the interlayer dielectric film 38 may remain without being bonded with the initial polycrystalline film 61, nitrogen or the like, and may configure a part of the first barrier metal layer 60.

Note that the step S110 may be omitted and the TiN film formed by nitriding the first initial metal film 67 may only form the first barrier metal layer 60. A TiN film formed by annealing has the structure finer than that of a TiN film deposited by sputtering to further ensure that the interlayer dielectric film 38 and the first alloy layer 62 are protected from a gas generated when depositing the plug layer 64 which will be described below.

The annealing process of the semiconductor substrate 10 in the nitrogen atmosphere may be divided into a process performed after the step 110 and a process in the step S112, where the former process is an annealing process for forming the first alloy layer 62 and the second alloy layer 63, and in addition, nitriding the remaining first initial metal film 67, and the latter process is an annealing process for increasing the adhesion performance of the second initial metal film 69. The respective annealing conditions may be the same or may be different. In addition, in another example, only the former annealing process before the step S110 may be performed while the latter annealing process after the step S110 may not be performed. The annealing process may be performed before forming the plug layer 64.

In the step S114, the plug layer 64 is formed. In the present example, a tungsten plug

layer 64 is formed by the CVD (Chemical Vapor Deposition) method to fill the contact hole 54 and to further be stacked on the interlayer dielectric film 38.

In the step S116, the plug layer 64 is etched back.

Accordingly, an unnecessary tungsten film outside the contact hole 54 may be removed. Etching back may be performed by dry etching or chemical mechanical polishing (CMP).

The second alloy layer 63 and the first barrier metal layer 60 on the upper surface of the interlayer dielectric film 38 may be removed by etching back after etching back the plug layer 64. After the steps S108, S110, and S112, the initial polycrystalline film 61, the first initial metal film 67, the second initial metal film 69, the second alloy layer 63, and the first barrier metal layer 60 on the upper surface of the interlayer dielectric film 38 may be removed.

Note that, the step S116 may be omitted and the plug layer 64 may remain on the outside of the contact hole 54. In addition, the steps S114 and S116 may be omitted and the plug layer 64 may not be formed.

After the step S116, the emitter electrode 52 may be formed above the semiconductor substrate 10. Further, after the step S116, the members on the back surface 23 side such as the collector electrode 24 may be formed. After the step S116, the back surface side lifetime control region 151 and the front surface side lifetime control region 152 may be formed.

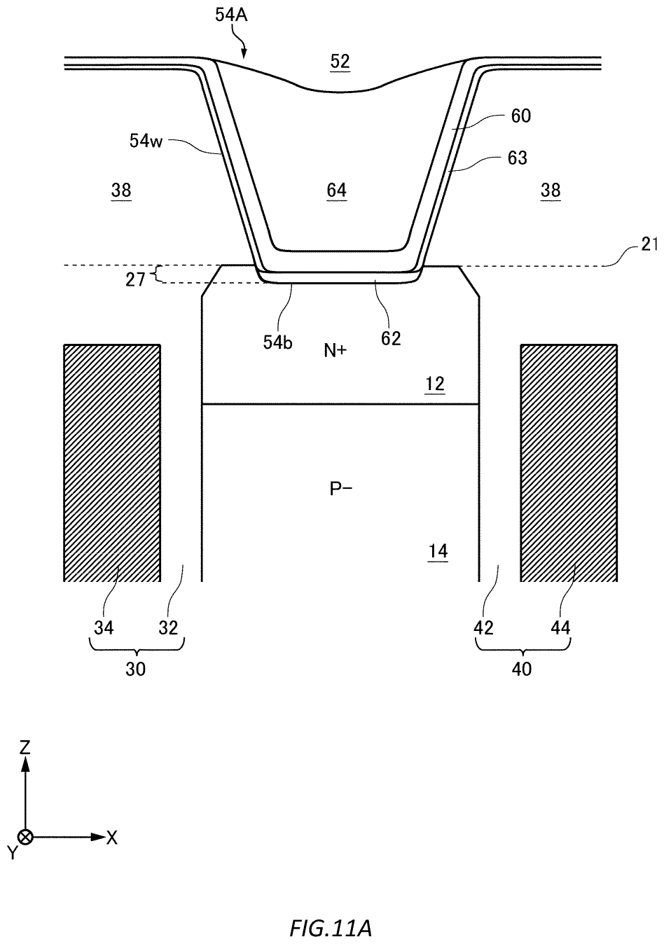

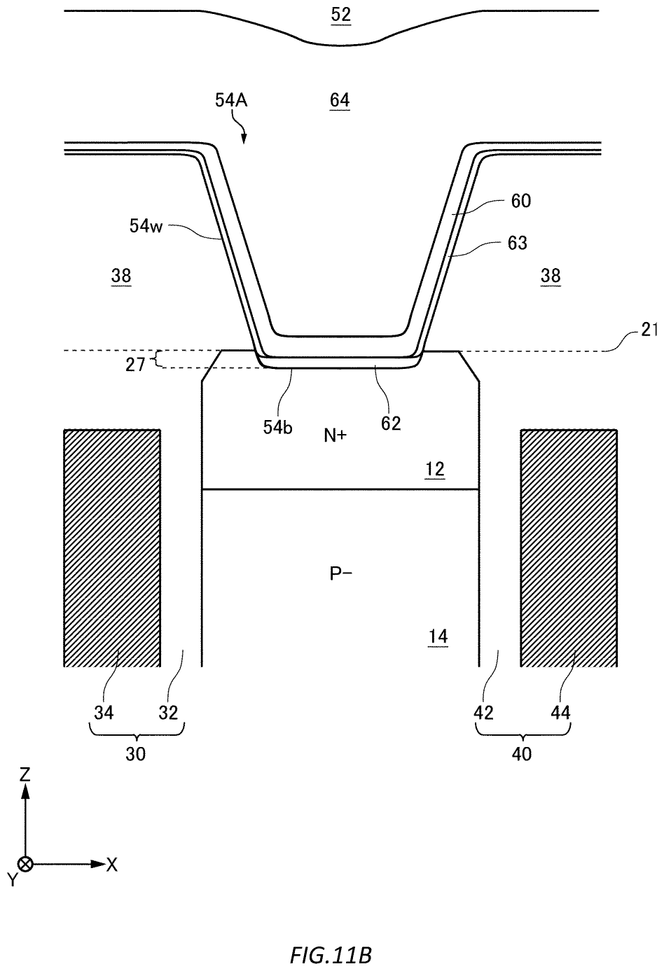

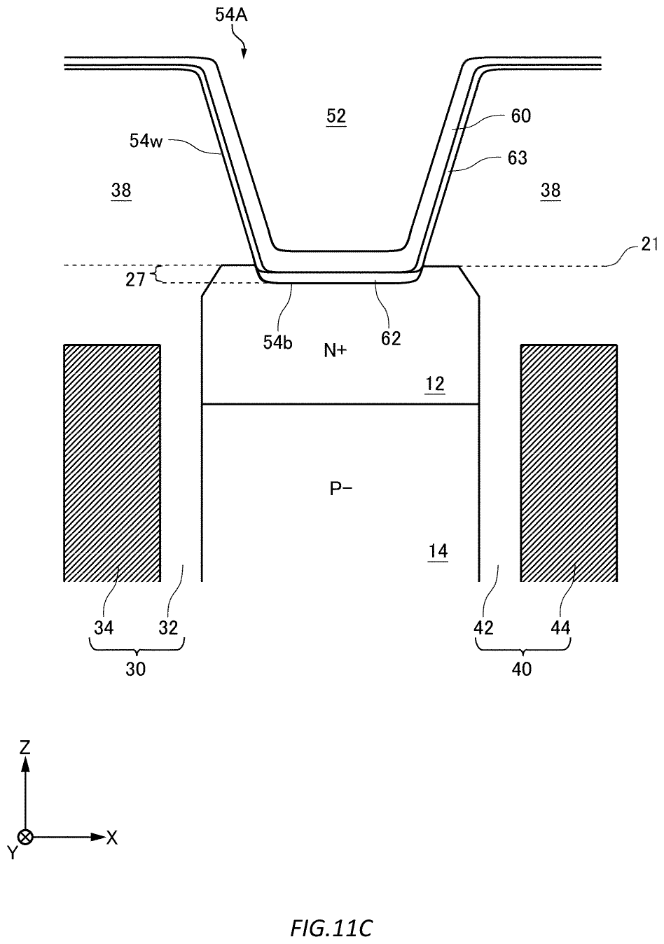

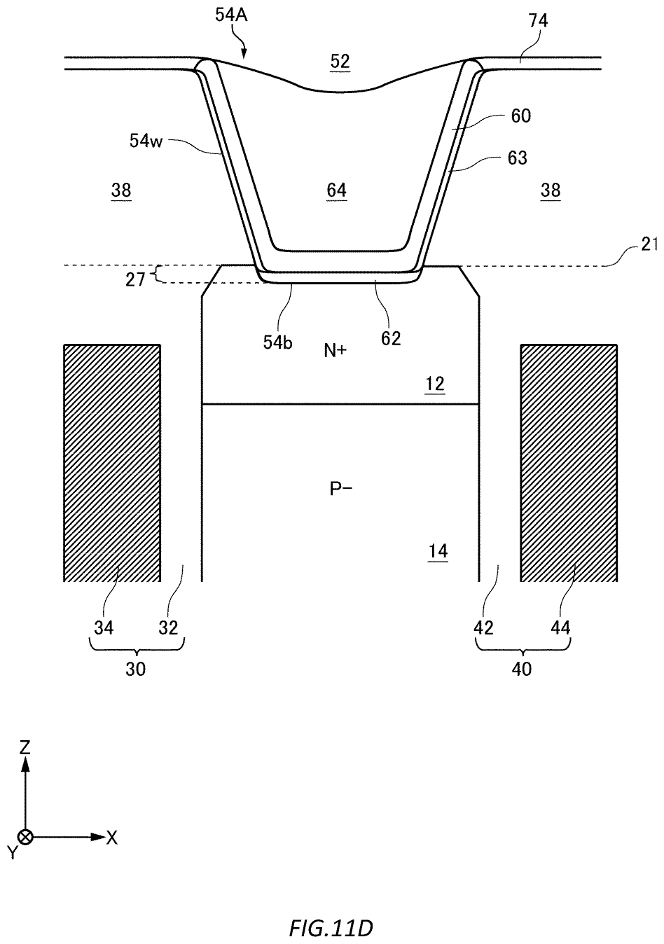

FIG. 11A, FIG. 11B, and FIG. 11C are enlarged views of a cross section of a variation example of the semiconductor device 100. In the example of FIG. 11A, FIG. 11B, and FIG. 11C, the configurations of the first barrier metal layer 60 and the second alloy layer 63 are different from those of FIG. 3A to FIG. 4C. FIG. 11A, FIG. 11B, and FIG. 11C show enlarged views of a cross section in the vicinity of the contact hole 54A. The cross section of FIG. 11A, FIG. 11B, and FIG. 11C is an XZ cross section passing through the emitter region 12 on the front surface 21 of the semiconductor substrate 10. Note that an XZ cross section passing through the contact region 15 on the front surface 21 of the semiconductor substrate 10 is the same as the XZ cross section of FIG. 11A, FIG.

11B, and FIG. 11C, except for the contact region 15 provided instead of the emitter region 12 of FIG. 11A, FIG. 11B, and FIG. 11C, and thus the illustration thereof is omitted.

In the example of FIG. 11A, the first barrier metal layer 60 and the second alloy layer 63 are different from those of FIG. 3A to FIG. 4C in being provided above the interlayer dielectric film 38 outside the contact hole 54A. The second alloy layer 63 may be provided in contact with the upper surface of the interlayer dielectric film 38 outside the contact hole 54A. This second alloy layer 63 may be the portion on the upper surface of the interlayer dielectric film 38 remaining without being removed by etching back in the step S116 of FIG. 10C.

The first barrier metal layer 60 may be provided in contact with the upper surface of the second alloy layer 63 outside the contact hole 54A. This first barrier metal layer 60 may be the portion above the interlayer dielectric film 38 remaining without being removed by etching back in the step S116 of FIG. 10C. The first barrier metal layer 60 is also formed on the interlayer dielectric film 38 so that the reliability of wire bonding, resin sealing and the like when mounted can be improved.

The example of FIG. 11B is different from that of FIG. 11A in the plug layer 64 provided above the interlayer dielectric film 38 outside the contact hole 54A. The plug layer 64 may be provided in contact with the first barrier metal layer 60 outside the contact hole 54A and above the interlayer dielectric film 38. The plug layer 64 is also provided above the interlayer dielectric film so that the reliability of wire bonding, resin sealing and the like when mounted can further be improved.

The example of FIG. 11C is different from that of FIG. 11A in the contact hole 54A not provided with the plug layer 64 and provided with the emitter electrode 52 instead. The emitter electrode 52 is connected to the front surface 21 of the semiconductor substrate 10 via the contact hole 54A. If the mesa is wide to provide a wide contact hole, it can directly be filled with the emitter electrode without the plug layer. Even in this case, the first barrier metal layer 60 is also formed on the interlayer dielectric film 38 so that the reliability of wire bonding, resin sealing and the like when mounted can be improved.

The example of FIG. 11D is different from that of FIG. 11A in the first barrier metal layer 60 and the second alloy layer 63 not provided on the upper surface of the interlayer dielectric film 38, and the second barrier metal layer 74 provided instead. After the step S106 of the manufacturing process shown in FIG. 9, and FIG. 10A to FIG. 10C, the initial polycrystalline film 61 on the upper surface of the interlayer dielectric film 38 around the contact hole 54A is removed so that the second barrier metal layer 74 is formed on the upper surface of the interlayer dielectric film 38. The second barrier metal layer 74 having a higher amount of the remaining first initial metal film 67 than that of the first barrier metal layer 60 is provided on the upper surface of the interlayer dielectric film 38 to obtain a higher anti-ion performance than that of the example shown in FIG. 11A. Note that the second barrier metal layer 74 may be interposed in this manner if the plug layer 64 is kept to remain above the interlayer dielectric film 38 as shown in FIG. 11B, or the second barrier metal layer 74 may be interposed in this manner if the contact hole 54A is filled with the emitter electrode instead of the plug layer as shown in FIG. 11C.

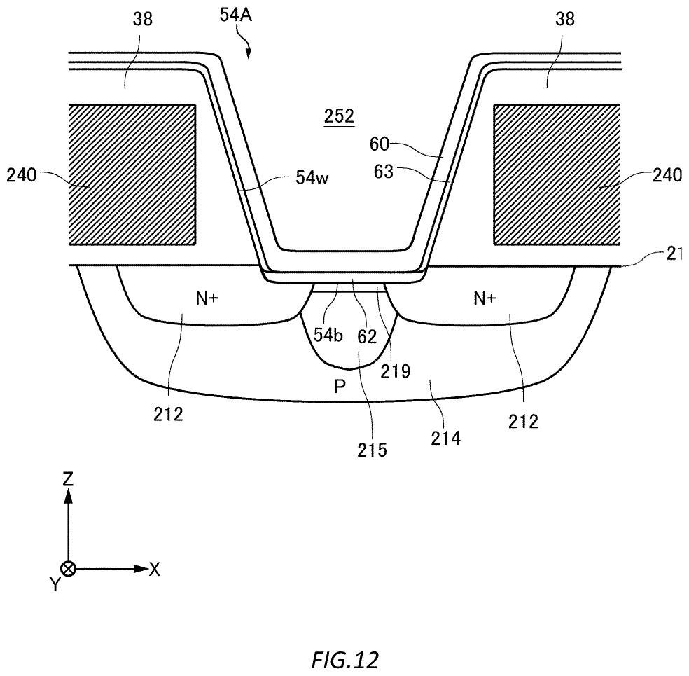

FIG. 12 is an enlarged view of a cross section of a variation example of the semiconductor device 100. The semiconductor device 100 of the present example includes the gate electrode 240 of a planar structure instead of the gate trench portion 40. The cross section of the present example is an XZ cross section passing through the source electrode 252, the interlayer dielectric film 38, the source region 212 of the first conductivity type, the base region 214 of the second conductivity type, the contact region 215 of the second conductivity type, the plug region 219 of the second conductivity type and the gate electrode 240 on the front surface 21 of the semiconductor substrate 10. The contact hole 54A is provided with the first barrier metal layer 60, the first alloy layer 62, and the second alloy layer 63.

The semiconductor device 100 of the present example may not include the plug layer 64. The planar structure can be provided with a wider interval than the trench structure so that the contact hole 54A may be filled with the source electrode 252.

In the present example, similarly to FIG. 11C, the first barrier metal layer 60 and the

second alloy layer 63 may be provided outside the contact hole 54A and above the interlayer dielectric film 38. Note that, in another example, the second alloy layer 63, the first barrier metal layer 60, and the plug layer 64 above the interlayer dielectric film 38 or on the side wall may be provided similarly to the contact hole 54A described using the figures shown in FIG. 3A to FIG. 11B, and the gate trench portion 40 may be provided rather than the gate electrode 240 having a planar structure.

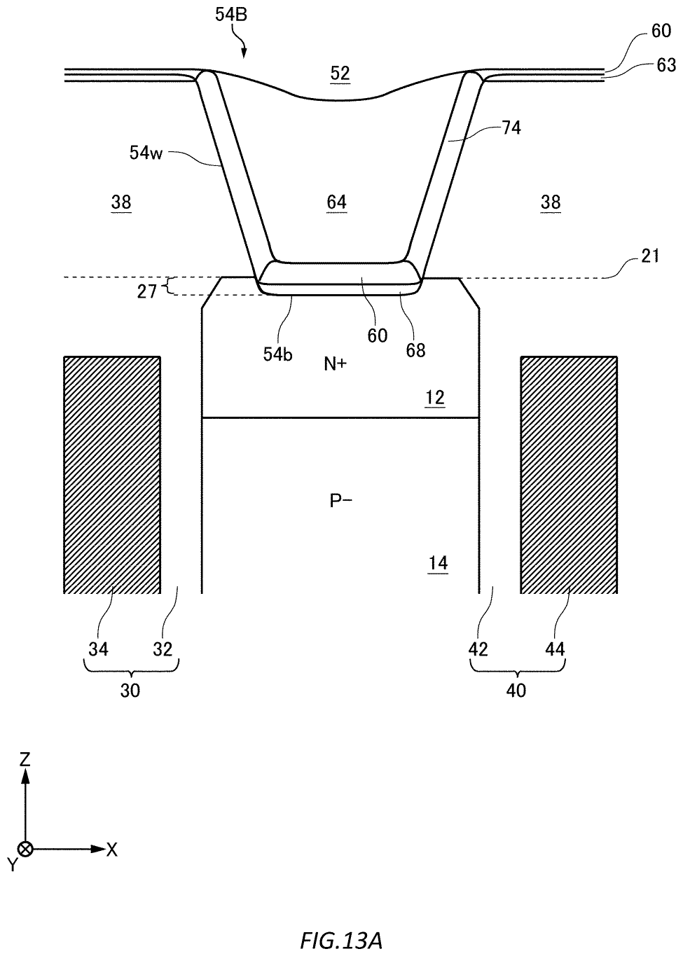

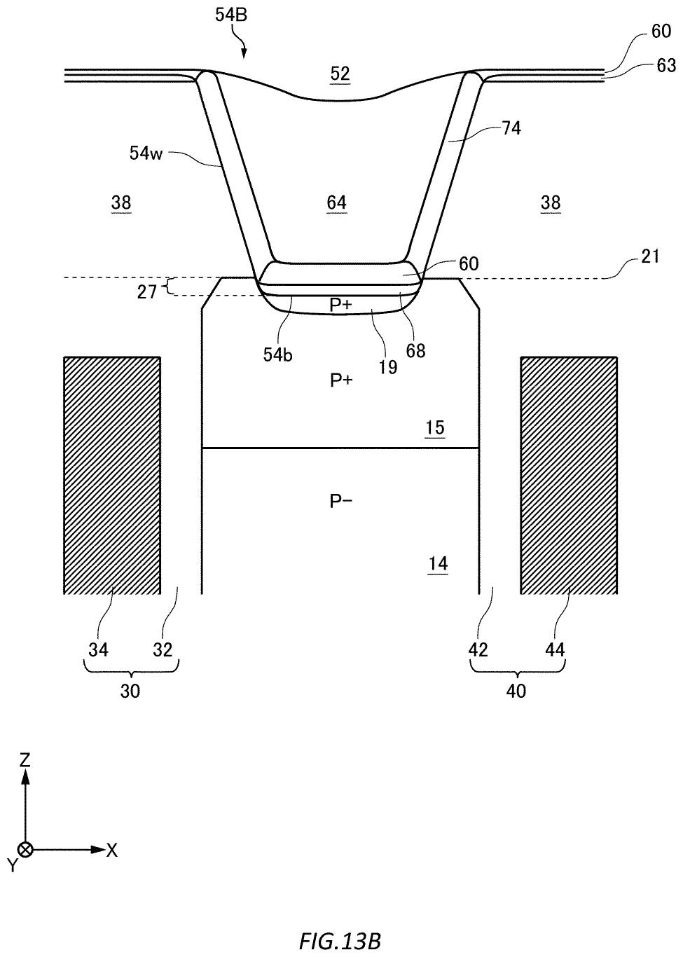

FIG. 13A is an enlarged view of a cross section of a semiconductor device 200. The semiconductor device 200 includes the same structure as that of the semiconductor device 100, except for the structure in the vicinity of the contact hole 54. Therefore, the same elements are provided with the same reference signs and the differences will mainly be described here.

The cross section of the present example is the XZ cross section which passes through the emitter region 12 at a front surface 21 of a semiconductor substrate 10. The contact hole 54B is provided with the third alloy layer 68, the first barrier metal layer 60, the second barrier metal layer 74, and the plug layer 64. In addition, the second alloy layer 63 and the first barrier metal layer 60 are provided above the interlayer dielectric film 38.

First, the structure in the contact hole 54B will be described. The third alloy layer 68 is provided to cover the bottom portion 54b of the contact hole 54B. The third alloy layer 68 of the present example is formed of Ti deposited on the bottom portion 54b of the contact hole 54B as the first initial metal film 67 bonded with silicon of the semiconductor substrate 10. The third alloy layer 68 is provided to obtain a good contact. For example, the third alloy layer 68 is TiSi₂.

On the side wall 54w of the contact hole 54B, the second barrier metal layer 74 is provided in contact with the interlayer dielectric film 38. The second barrier metal layer 74 may be a stacking structure formed of the portion of the first initial metal film 67 deposited on the side wall 54w of the contact hole 54B for forming the third alloy layer 68 and remaining without being bonded with nitrogen or the like, and a TiN film formed by sputtering as the second initial metal film 69. In addition, it may further include a TiN film formed by annealing Ti deposited on the side wall 54w of the contact hole 54B as the first initial metal film 67 in the nitrogen atmosphere.

On the bottom portion 54b of the contact hole 54B, the first barrier metal layer 60 is provided to be stacked on the third alloy layer 68. The first barrier metal layer 60 may be a TiN film formed by sputtering as the second initial metal film 69. In addition, it may further include the first initial metal film 67 deposited on the bottom portion 54b of the contact hole 54B for forming the third alloy layer 68 and remaining without being bonded with the semiconductor substrate 10, nitrogen or the like, and a TiN film formed by anneal Ti deposited on the bottom portion 54b of the contact hole 54B as the first initial metal film 67 in the nitrogen atmosphere.

The plug layer 64 is provided in contact with the first barrier metal layer 60 and second barrier metal layer 74 in the contact hole 54B. For example, the material of the plug layer 64 is tungsten. Use of tungsten having a good embeddability can miniaturize the device structure of the front surface. The plug layer 64 may also be provided above the interlayer dielectric film 38.

The first barrier metal layer 60 and the second barrier metal layer 74 are provided in the contact hole 54B to improve the adhesion performance of the plug layer 64. In addition, the first barrier metal layer 60 and the second barrier metal layer 74 are provided to avoid erosion of the interlayer dielectric film 38 and the third alloy layer 68 due to a gas generated when depositing the plug layer 64.

Then, the structure of the upper surface of the interlayer dielectric film 38 in the vicinity of the contact hole 54B will be described. The second alloy layer 63 is provided on the upper surface of the interlayer dielectric film 38. The second alloy layer 63 of the present example is an alloy layer formed as a result of reaction of polycrystalline. For example, the second alloy layer 63 is TiSi₂ formed by annealing the initial polycrystalline film 61 of polysilicon and the first initial metal film 67 of Ti deposited on the upper surface of the interlayer dielectric film 38. The third alloy layer 68 and the second alloy layer 63 may be formed by the same annealing process.

The first barrier metal layer 60 is provided to be stacked on the second alloy layer 63. The first barrier metal layer 60 may be a TiN film formed by sputter as the second initial metal film 69. In addition, it may further include the first initial metal film 67 deposited on the upper surface of the interlayer dielectric film 38 for forming the second alloy layer 63 and remaining without being bonded with the initial polycrystalline film 61, nitrogen or the like, and a TiN film formed by annealing Ti deposited on the upper surface of the interlayer dielectric film 38 as the first initial metal film 67 in the nitrogen atmosphere. The first barrier metal layer 60 is provided on the upper surface of the interlayer dielectric film 38 to improve the anti-ion permeability performance.

According to the semiconductor device 200 of the present example, the initial polycrystalline film 61 deposited to form the second alloy layer 63 is bonded with the first initial metal film 67 above the interlayer dielectric film 38 to prevent the first initial metal film 67 having a hydrogen absorbing effect from remaining and reduce the remaining amount. Thus, the influence of the hydrogen absorbing effect can be suppressed and the hydrogen termination of dangling bonds of the MOS gate structure can be facilitated. Accordingly, a variation of a threshold voltage can be suppressed.

FIG. 13B is an enlarged view of the cross section of the semiconductor device 200. The cross section of the present example passes through the contact region 15 on the front surface 21 of the semiconductor substrate 10, unlike the cross section of FIG. 13A. In the present example, a difference from FIG. 13A will be particularly described.

The plug region 19 of the P+ type having a doping concentration higher than that of the contact region 15 may be provided below the contact hole 54B. The plug region 19 may be provided in a region below the contact hole 54B and above the contact region 15. A lower end of the plug region 19 may be provided to be shallower than a lower end of the contact region 15. The hole is extracted from the contact region 15 and the plug region 19 via the contact hole 54. The plug region 19 improves the contact resistance between the third alloy layer 68 of the contact hole 54B and the contact region 15 to improve the latch up withstand capability.

The plug region 19 may be provided in a region below the contact hole 54B and above the base region 14. The plug region 19 may be provided in the mesa portion 71 and the mesa portion 91. The plug region 19 may not be provided in a region below the contact hole 54 and above the emitter region 12. In this case, the plug regions 19 may be provided discretely along the contact hole 54B to correspond to the repeated structure of the emitter regions 12 and the contact regions 15 in the mesa portion 71 and the mesa portion 91.

If the mesa portion 81 is provided with the contact hole 54B, the plug region 19 is

provided below the contact hole 54B. This improves the contact resistance between the base region 14 and the first alloy layer 62. Note that the plug region 19 may not be provided in the entire region of the contact region 15 and the base region 14, or may be provided partially or discretely. This suppresses hole injection from the region where the plug region 19 is not formed into the semiconductor substrate 10 when the diode portion 80 is in conduction.

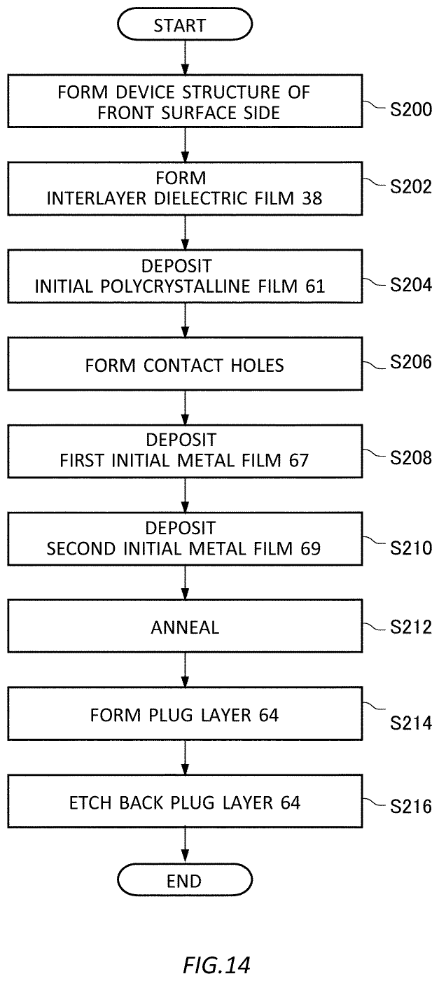

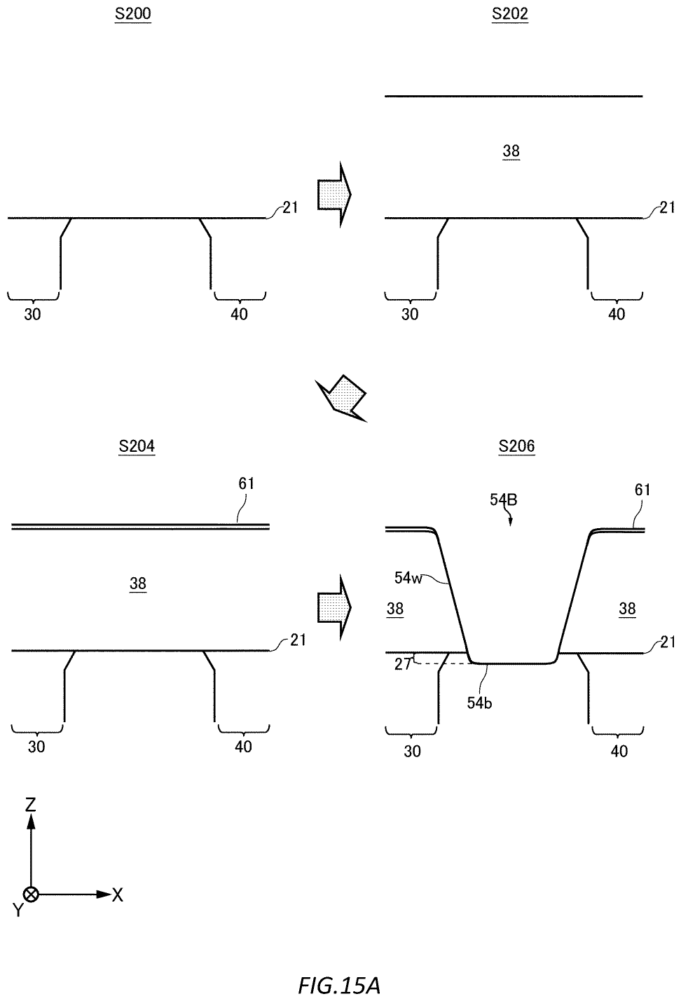

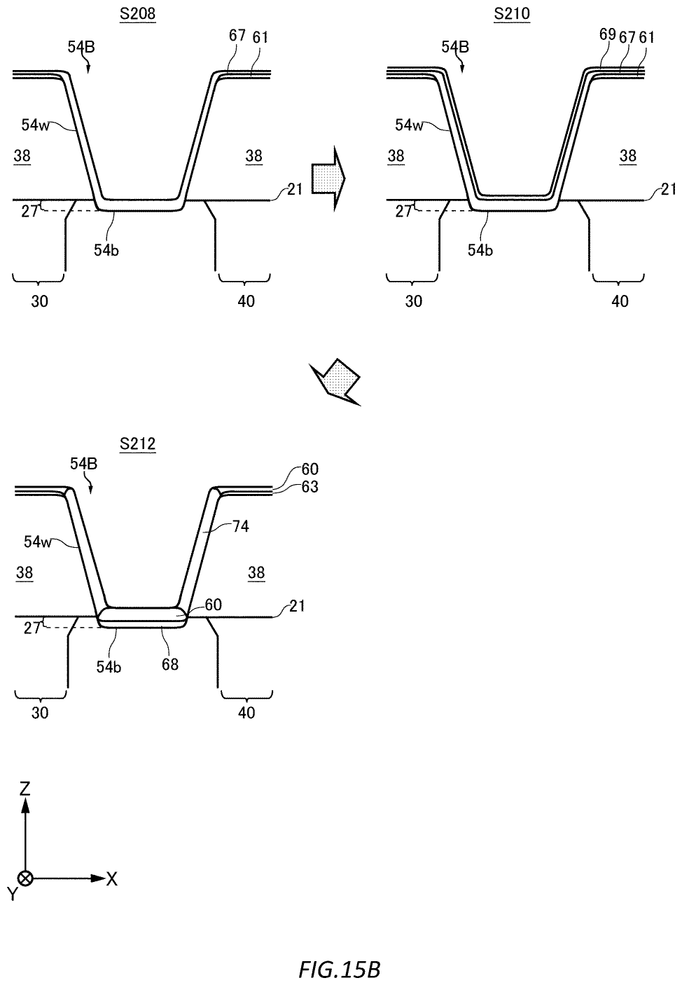

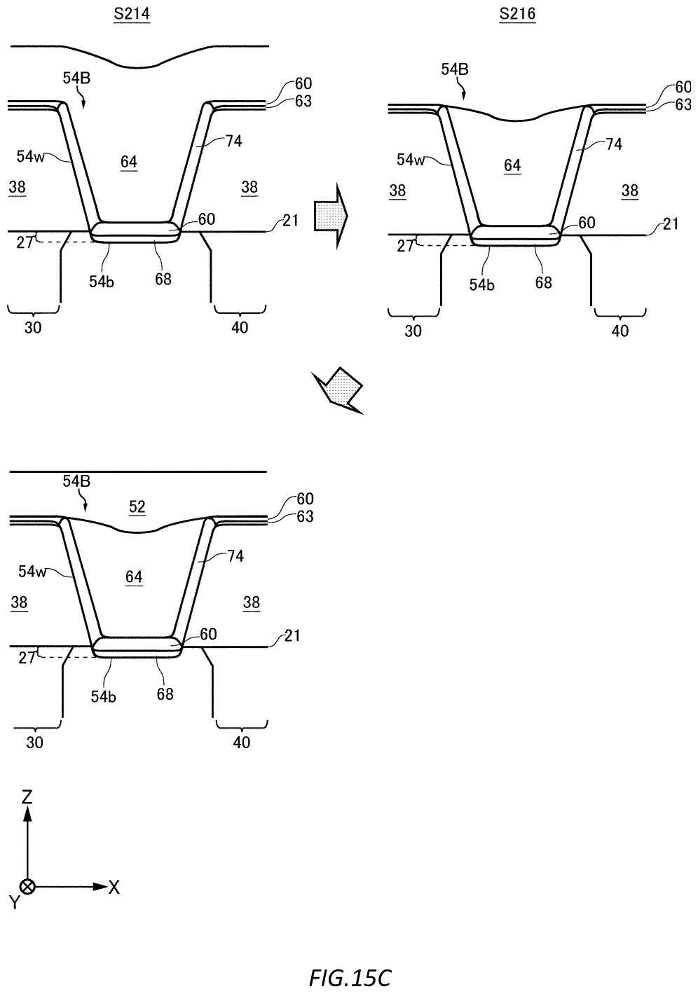

FIG. 14 is a flowchart showing an example of a manufacturing process of the semiconductor device 200. FIG. 15A to FIG. 15C are diagrams showing an example of a manufacturing process of the semiconductor device 200. Here, an example of the manufacturing process of the semiconductor device 200 will be described with reference to each process shown in FIG. 15A to FIG. 15C as appropriate.

In the step S200, a device structure of the front surface 21 side of the semiconductor substrate 10 is formed. The step S200 may include a process of forming the dummy trench portion 30 and the gate trench portion 40 as the device structure on the front surface 21 side. The step S200 may include a process of forming the base region 14, the emitter region 12 and the contact region 15 or the like as the device structure of the front surface 21 side by ion implantation into the semiconductor substrate 10.

In the step S202, the interlayer dielectric film 38 is formed above the front surface 21 of the semiconductor substrate 10. The interlayer dielectric film 38 may be a silicon oxide film such as BPSG. The interlayer dielectric film 38 may be formed by stacking a plurality of dielectric films.

In the step S204, the initial polycrystalline film 61 is deposited on the upper surface of the interlayer dielectric film 38. Preferably, the initial polycrystalline film 61 is deposited to have a film thickness so that the first initial metal film 67 does not remain on the upper surface of the interlayer dielectric film 38 after the step S212 which will be described below.

In the step S206, the contact hole is formed by etching the interlayer dielectric film 38. Here, the recessed portion 27 is formed by over-etching the front surface 21 of the semiconductor substrate 10. In other words, the contact hole 54B having a sufficient dimension can be formed by keeping on etching after reaching the front surface 21 of the semiconductor substrate 10 until the recessed portion 27 is formed. The trench contact portion 65 may further be formed. In addition, the plug region 19 may be formed between the step S206 and the step S208.

The step S206 is performed after the step S204. That is, when the step S206 is completed, silicon of the semiconductor substrate 10 and the interlayer dielectric film 38 are exposed to the bottom portion 54b and the side wall 54w of the contact hole 54B, respectively, and the initial polycrystalline film 61 only remains on the upper surface of the interlayer dielectric film 38 surrounding the contact hole 54B. In addition, in the step S206, contact holes such as the contact hole 54B, the contact hole 55, and the contact hole 56 may be formed in the interlayer dielectric film 38.

In the step S208, the first initial metal film 67 is deposited on the inner wall of the contact hole 54B and above the interlayer dielectric film 38. For example, the first initial metal film 67 is a Ti film deposited by sputtering. The first initial metal film 67 is formed in contact with silicon of the semiconductor substrate 10 and the interlayer dielectric film 38 on the bottom portion 54b and the side wall 54w of the contact hole 54B, respectively. The first initial metal film 67 is deposited in contact with the upper surface of the initial polycrystalline film 61 above the interlayer dielectric film 38.

In the step S210, the second initial metal film 69 is deposited on the first initial metal film 67 in the contact hole 54B and above the interlayer dielectric film 38. For example, the second initial metal film 69 is a TiN film deposited by sputtering. The second initial metal film 69 is formed to be stacked on the first initial metal film 67.

In the step S212, the semiconductor substrate 10 is annealed in a nitrogen atmosphere. This causes silicon of the semiconductor substrate 10 and the first initial metal film 67 to be silicided on the bottom portion 54b of the contact hole 54B to form the third alloy layer 68. The third alloy layer 68 of the present example is TiSi₂. The first initial metal film 67 deposited on the bottom portion 54b of the contact hole 54B is bonded with silicon of the semiconductor substrate 10 to be replaced with the third alloy layer 68. On the bottom portion 54b of the contact hole 54B, the third alloy layer 68 is formed in contact with the front surface 21 of the semiconductor substrate 10 and the first barrier metal layer 60 is formed in contact with the upper surface of the third alloy layer 68.

In addition, by annealing in the step S212, the first initial metal film 67 is nitrided on the side wall 54w of the contact hole 54B to form a TiN film. In addition, a part of the first initial metal film 67 deposited on the side wall 54w of the contact hole 54B may remain without being bonded with nitrogen or the like. A stacking structure of a Ti layer and a TiN layer may be formed on the side wall 54w of the contact hole 54B. The Ti layer is the remaining first initial metal film 67 and provided in contact with the interlayer dielectric film 38. The TiN layer may be a stacking structure of the second initial metal film 69 and a TiN film formed of the nitrided first initial metal film 67. The Ti layer and the TiN layer in the contact hole 54B are an example of the second barrier metal layer 74.

Note that the step S210 may be omitted and the TiN film formed by nitriding the first initial metal film 67 may only form the second barrier metal layer 74. A TiN film formed by annealing has the structure finer than that of a TiN film deposited by sputtering to further ensure that the interlayer dielectric film 38 and the third alloy layer 68 are protected from a gas generated when depositing the plug layer 64 which will be described below.

In addition, by annealing in the step S212, the initial polycrystalline film 61 and the first initial metal film 67 are silicided on the upper surface of the interlayer dielectric film 38 to form the second alloy layer 63. The second alloy layer 63 of the present example is TiSi₂. Above the interlayer dielectric film 38, the first initial metal film 67 is bonded with the initial polycrystalline film 61 to be replaced with the second alloy layer 63. Accordingly, the first initial metal film 67 does not remain or the remain amount is small above the interlayer dielectric film 38 so that the influence of the hydrogen absorbing effect of the first initial metal film 67 can be suppressed and the hydrogen termination of dangling bonds of the MOS gate structure can be facilitated. Accordingly, a variation of a threshold voltage can be suppressed.

In addition, by annealing in the step S212, the first barrier metal layer 60 is provided to be stacked on the second alloy layer 63 on the upper surface of the interlayer dielectric film 38. The first barrier metal layer 60 may be a TiN film formed by sputter as the second initial metal film 69. In addition, it may further include the first initial metal film 67 deposited on the upper surface of the interlayer dielectric film 38 for forming the second alloy layer 63 and remaining without being bonded with the initial polycrystalline film 61, nitrogen or the like, and a TiN film formed by annealing Ti deposited on the upper surface of the interlayer dielectric film 38 as the first initial metal film 67 in the nitrogen atmosphere. The first barrier metal layer 60 is provided on the upper surface of the interlayer dielectric film 38 to improve the anti-ion permeability performance.

Note that the semiconductor substrate 10 may also be annealed before the step S210. In this case, the annealing process may be divided into two processes: a process performed after depositing the first initial metal film 67; and a process performed after depositing the second initial metal film 69. The former process is an annealing process for forming the third alloy layer 68 and the second alloy layer 63 and for nitriding the remaining first initial metal film 67, and the latter process is an annealing process for increasing the adhesion performance of the second initial metal film 69. These annealing conditions may be the same or may be different. In addition, in another example, only the former annealing process before the step S210 may be performed while the latter annealing process after the step S210 may not be performed. The annealing process may be performed before forming the plug layer 64.

In the step S214, the plug layer 64 is formed. In the present example, a tungsten plug layer 64 is formed by the CVD (Chemical Vapor Deposition) method to fill the contact hole 54B. As described above, the second barrier metal layer 74 and the first barrier metal layer 60 are provided on the inner wall of the contact hole 54 so that erosion of the interlayer dielectric film 38 and the third alloy layer 68 due to a gas generated when depositing the plug layer 64 can be avoided.

In the step S216, the plug layer 64 is etched back. Accordingly, an unnecessary tungsten film outside the contact hole 54B may be removed. Etching back may be performed by dry etching or chemical mechanical polishing (CMP). Note that, the step S216 may be omitted and the plug layer 64 may remain on the outside of the contact hole 54B.

After the step S216, the emitter electrode 52 may be formed above the semiconductor substrate 10. In addition, after the step S216, the members on the back surface 23 side such as the collector electrode 24 may be formed. After the step S216, the back surface side lifetime control region 151 and the front surface side lifetime control region 152 may be formed. Note that, the step

S216 may be omitted and the plug layer 64 may remain on the outside of the contact hole 54B. In addition, the steps S214 and S216 may be omitted so that the plug layer 64 is not formed.

In this manner, according to the manufacturing method of the semiconductor device 200, the second barrier metal layer 74 and the first barrier metal layer 60 including the Ti layer and the TiN layer are formed in the contact hole 54B so that the anti-ion permeability performance can be improved. In addition, the second barrier metal layer 74 and the first barrier metal layer 60 are formed to avoid erosion of the interlayer dielectric film 38 and the third alloy layer 68 due to a gas generated when depositing the plug layer 64.

In addition, according to the manufacturing method of the semiconductor device 200, the initial polycrystalline film 61 is deposited on the upper surface of the interlayer dielectric film 38 before forming the contact hole 54B so that the interlayer dielectric film 38 deposited above the first initial metal film 67 is bonded with the initial polycrystalline film 61 to be replaced with the second alloy layer 63. In addition, accordingly, while the Ti layer is formed in the contact hole 54 to improve the anti-ion permeability performance due to the second barrier metal layer 74, Ti above the interlayer dielectric film 38 is removed to suppress the influence due to the Ti hydrogen absorbing effect to improve the anti-ion permeability performance due to the first barrier metal layer 60 while facilitating the hydrogen termination of the dangling bond of the MOS gate structure. Accordingly, a variation of a threshold voltage can be suppressed.

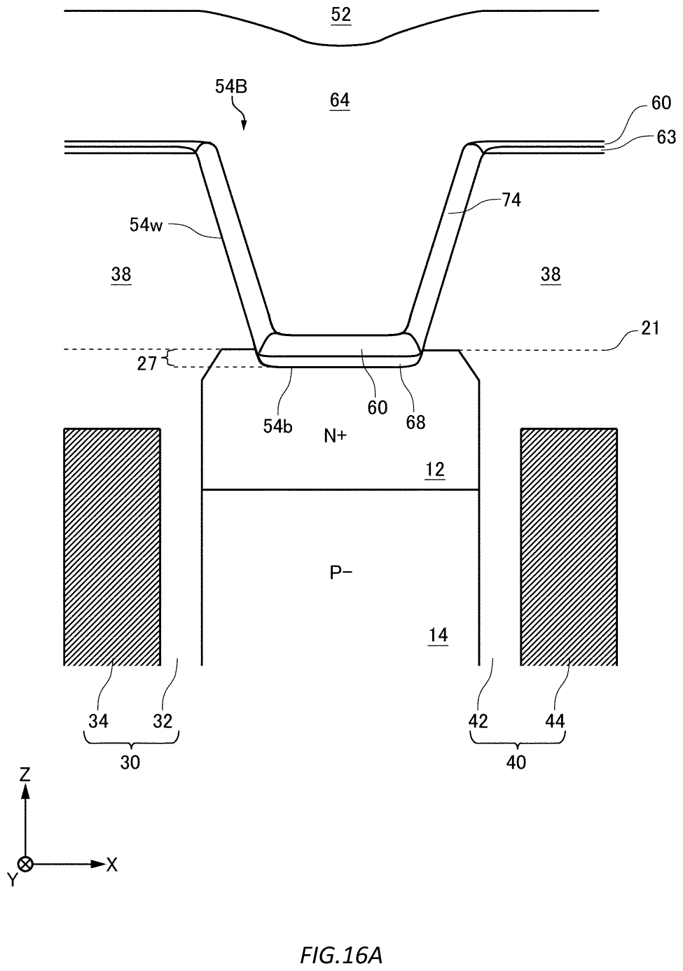

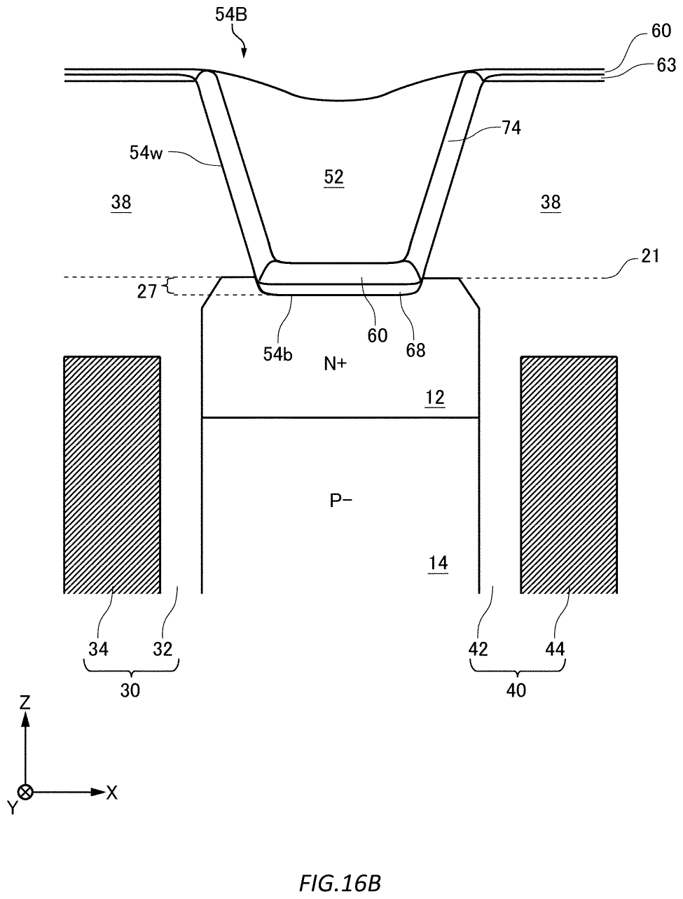

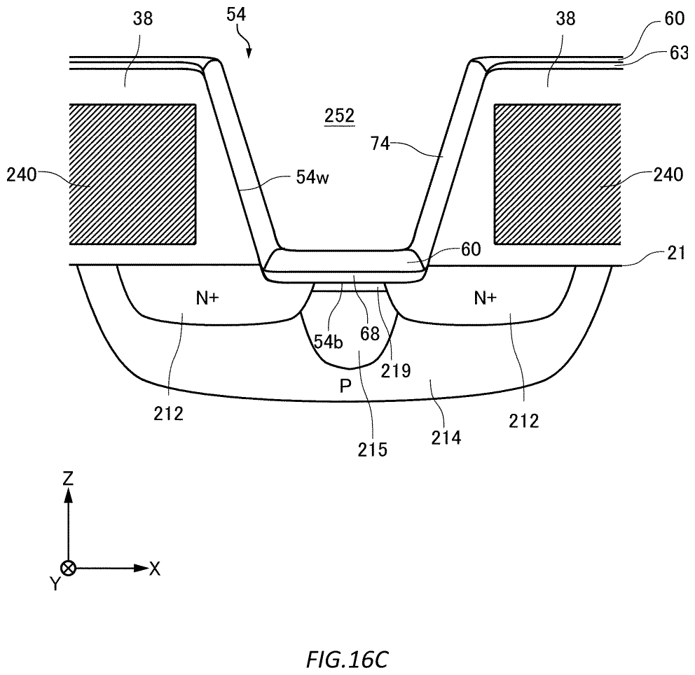

FIG. 16A, FIG. 16B, and FIG. 16C are enlarged views of a cross section of a variation example of the semiconductor device 200. In the examples of FIG. 16A, FIG. 16B, and FIG. 16C, the configuration of the plug layer 64 is different from those of FIG. 13A and FIG. 13B. FIG. 16A, FIG. 16B, and FIG. 16C show enlarged views of a cross section in the vicinity of the contact hole 54B.

The cross section of FIG. 16A is an XZ cross section passing through the emitter region 12 on the front surface 21 of the semiconductor substrate 10. The example of FIG. 16A is different from that of FIG. 13A in the plug layer 64 provided above the interlayer dielectric film 38 outside the contact hole 54B. The plug layer 64 may be provided in contact with the first barrier metal layer 60 outside the contact hole 54 and above the interlayer dielectric film 38. Note that an XZ cross section passing through the contact region 15 on the front surface 21 of the semiconductor substrate 10 is the same as the XZ cross section of FIG. 16A, except for the contact region 15 provided instead of the emitter region 12 of FIG. 16A, and thus the illustration thereof is omitted.

The cross section of FIG. 16B is an XZ cross section passing through the emitter region 12 on the front surface 21 of the semiconductor substrate 10. The example of FIG. 16B is different from that of FIG. 13A in the contact hole 54B not provided with the plug layer 64 and provided with the emitter electrode 52 instead. The emitter electrode 52 is connected to the front surface 21 of the semiconductor substrate 10 via the contact hole 54B. Note that an XZ cross section passing through the contact region 15 on the front surface 21 of the semiconductor substrate 10 is the same as the XZ cross section of FIG. 16B, except for the contact region 15 provided instead of the emitter region 12 of FIG. 16B, and thus the illustration thereof is omitted.

In the example of FIG. 16C, the gate electrode 240 of a planar structure is provided instead of the gate trench portion 40. The cross section of the present example is an XZ cross section passing through the source electrode 252, the interlayer dielectric film 38, the source region 212 of the first conductivity type, the base region 214 of the second conductivity type, the contact region 215 of the second conductivity type, the plug region 219 of the second conductivity type and the gate electrode 240 on the front surface 21 of the semiconductor substrate 10. The contact hole 54B is provided with the third alloy layer 68 and the first barrier metal layer 60 on the bottom portion 54b and the second barrier metal layer 74 on the side wall 54w. In addition, the second alloy layer 63 and the first barrier metal layer 60 are provided above the interlayer dielectric film 38.

The semiconductor device 200 of the present example may not include the plug layer 64. The planar structure can be provided with a wider interval than the trench structure so that the contact hole 54B may be filled with the source electrode 252. Note that, in another example, the second alloy layer 63, the first barrier metal layer 60, the second barrier metal layer 74, and the plug layer 64 above the interlayer dielectric film 38 or on the side wall may be provided similarly to the contact hole 54B described using the figures shown in FIG. 13A to FIG. 16A, and the gate trench portion 40 may be provided rather than the gate electrode 240 having a planar structure.

In this manner, the structures of inside of the contact hole 54B and the upper surface of the interlayer dielectric film 38 described with reference to FIG. 13A and FIG. 13B can be applied to the semiconductor device 200 of the present example.

Note that the contact hole 54B of the semiconductor device 200 shown in FIG. 13A and FIG. 13B can also be formed by, in the manufacturing process for forming the semiconductor device 100 shown in FIG. 9, and FIG. 10A to FIG. 10C, after forming the contact hole 54 in the step S104 and depositing the initial polycrystalline film 61 in the step S106, removing the initial polycrystalline film 61 in the contact hole 54B while keeping only a portion thereof on the upper surface of the interlayer dielectric film 38 remains and performing the step S108 and the subsequent processes. If the contact hole 54B is formed in this manufacturing process, a part of the initial polycrystalline film 61 may be removed without leaving it remaining on the entire upper surface of the interlayer dielectric film 38. For example, the boundary of a region where the initial polycrystalline film 61 remains may not align with an opening of the contact hole 54B, and the boundary between the second barrier metal layer 74 and the first barrier metal layer 60 and the second alloy layer 63 may be on the upper surface of the interlayer dielectric film 38. In this manner, the semiconductor device 100 including the contact holes 54A and 54B may be manufactured in the manufacturing process of partially removing the initial polycrystalline film 61 deposited after forming the contact hole 54. For example, although the example of FIG. 7 is described as including the contact hole 54A shown in FIG. 3A and the contact hole 54B shown in FIG. 5A, it is not limited thereto. For example, it may also include the contact hole 54A shown in FIG. 11A and the contact hole 54B shown in FIG. 13A, or the contact hole 54B including the second barrier metal layer 74 on the upper surface of the interlayer dielectric film 38 or the like.

In addition, the semiconductor device 200 only including the contact hole 54B may also be manufactured in the aforementioned manufacturing process of partially removing the initial polycrystalline film 61 deposited after forming the contact hole 54. It may only include the contact hole 54B shown in FIG. 13A and FIG. 13B formed in this manner, or otherwise may include the contact holes 54B of different structures such as the contact hole 54B shown in FIG. 5A and FIG. 5B, and the contact hole 54B with the second barrier metal layer 74 on the upper surface of the interlayer dielectric film 38.

In addition, the semiconductor device 100 including the contact hole 54A and the contact hole 54B can also be formed by: in the manufacturing process of forming the semiconductor device 100 shown in FIG. 9, and FIG. 10A to FIG. 10C, forming the contact hole 54A in the step S104; forming, after depositing the initial polycrystalline film 61 in the step S106, the contact hole 54B in the interlayer dielectric film 38 on which the initial polycrystalline film 61 is deposited; and performing the step S108 and the subsequent steps. The process of forming the contact hole 54B is identical to that of the manufacturing process of the semiconductor device 200 shown in FIG. 14, and FIG. 15A to FIG. 15C. In this manner, even if the initial polycrystalline film 61 is not removed in the process, the semiconductor device 100 including the contact holes 54A and 54B can be manufactured. That is, the semiconductor device 100 including the contact hole 54A shown in FIG. 11A and the contact hole 54B shown in FIG. 13A can be obtained if the emitter electrode 52 is formed after the step S116, the semiconductor device 100 including the contact hole 54A shown in FIG. 3A and the contact hole 54B shown in FIG. 5A can be obtained if the first barrier metal layer 60 and the second alloy layer 63 are further removed after the step S116 and the emitter electrode 52 is formed, the semiconductor device 100 including the contact hole 54A shown in FIG. 11B and the contact hole 54B shown in FIG. 16A can be obtained if the step S116 is omitted and the emitter electrode 52 is formed, and the semiconductor device 100 including the contact hole 54A shown in FIG. 11C and the contact hole 54B shown in FIG. 16B can be obtained if the step S114 is omitted and the emitter electrode 52 is formed.

In the examples described above, the first alloy layer 62 on the bottom portion 54b of the contact hole 54A is formed from the initial polycrystalline film 61 on the bottom portion 54b deposited after forming the contact hole. However, this is not limited to these examples. Only a portion of the initial polycrystalline film 61 of the step S106 shown in FIG. 9 and FIG. 10B on the bottom portion 54b of the contact hole may be removed to form the first alloy layer 62 from silicon of the mesa portion of the bottom portion 54b of the contact hole, that is, from the underlying layer. Even in this case, the second alloy layer 63 is formed on the side wall 54w of the contact hole such that the first initial metal film 67 of the first barrier metal layer 60 on the side wall 54w of the contact hole is removed or made thinner to suppress the variation of the threshold. In addition, carrier injection through the bottom portion 54b of the contact hole can be adjusted in the different manner from those described in the aforementioned examples, as an increase in the amount of silicide transformed from silicon of the mesa portion results in a decrease in the high concentration regions.

On the other hand, in the aforementioned examples, the third alloy layer 68 on the bottom portion 54b of the contact hole 54B is formed from silicon of the mesa portion of the bottom portion 54b of the contact hole, that is, from the underlying layer. However, this is not limited to these examples. The initial polycrystalline film 61 of the step S106 shown in FIG. 9 and FIG. 10B may be removed from the side wall 54w of the contact hole so that the third alloy layer 68 is formed from the initial polycrystalline film 61 on the bottom portion 54b. Even in this case, if the second alloy layer 63 is formed on the upper surface of the interlayer dielectric film 38 around the contact hole 54B, the first initial metal film 67 of the first barrier metal layer 60 on the upper surface of the interlayer dielectric film 38 is removed or made thinner to suppress the variation of the threshold. In addition, carrier injection through the bottom portion 54b of the contact hole can be adjusted in the different manner from those described in the aforementioned examples, as a decrease in the amount of silicide transformed from silicon of the mesa portion results in the remaining high concentration regions and the impurity-implanted polycrystalline layer 66 may be provided.

In addition, the structure similar to those of the contact hole 54A and the contact hole 54B described in the aforementioned examples may be applied to contact holes other than those in the active portion 120 such as the contact hole 55 and the contact hole 56 for connecting the emitter electrode 52 and the underlying layer such as the emitter region 12, the contact region 15, the base region 14, and the plug region 19. The contact hole 55 provided on the connection portion 25 which is the underlying layer as shown in FIG. 1A and FIG. 2B or on the gate conductive portion 44 of the example different from FIG. 1A and FIG. 2B, the contact hole 56 provided on the dummy conductive portion 34 as shown in FIG. 1A and FIG. 2B or the connection portion 25 of the example different from FIG. 1A and FIG. 2B, or the polysilicon diode of the temperature sensing diode not shown in the figure, contact holes provided on the field plate, the guard ring or the like of the edge termination structure portion 140 can also suppress the variation of the threshold of the active portion 120 by, if the second alloy layer 63 is formed on the upper surface of the interlayer dielectric film 38 or on the side wall of the contact hole, removing or making thinner the first initial metal film 67 of the first barrier metal layer 60 provided in contact with the second alloy layer 63.

While the present invention has been described by way of the embodiments, the technical scope of the present invention is not limited to the above-described embodiments. It is apparent to persons skilled in the art that various alterations or improvements can be made to the above-described embodiments. It is also apparent from the described scope of the claims that the embodiments to which such alterations or improvements are made can be included in the technical scope of the present invention.

It should be noted that the operations, procedures, steps, stages, or the like of each process performed by a device, system, program, and method shown in the claims, the specification, or the drawings can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 19: plug region, 20: buffer region, 21: front surface, 22: collector region, 23: back surface, 24: collector electrode, 25: connection portion, 27: recessed portion, 30: dummy trench portion, 31: extending portion, 32: dummy dielectric film, 33: connecting portion, 34: dummy conductive portion, 38: interlayer dielectric film, 40: gate trench portion, 41: extending portion, 42: gate dielectric film, 43: connecting portion, 44: gate conductive portion, 50: gate metal layer, 52: emitter electrode, 54: contact hole, 55: contact hole, 56: contact hole, 60: first barrier metal layer, 61: initial polycrystalline film, 62: first alloy layer, 63: second alloy layer, 64: plug layer, 65: trench contact portion, 66: impurity-implanted polycrystalline layer, 67: first initial metal film, 68: third alloy layer, 69: second initial metal film, 70: transistor portion, 71: mesa portion, 74: second barrier metal layer, 80: diode portion, 81: mesa portion, 82: cathode region, 85: extension region, 90: boundary region, 91: mesa portion, 100: semiconductor device, 102: end side, 112: gate pad, 120: active portion, 130: outer circumferential gate runner, 131: inter-active-portion gate runner, 140: edge termination structure portion, 151: back surface side lifetime control region, 152: front surface side lifetime control region, 212: source region, 214: base region, 219: plug region, 240: gate electrode, 252: source electrode

What is claimed is:

1. A semiconductor device including an MOS gate structure, comprising:
an underlying layer provided on a front surface of a semiconductor substrate or above the semiconductor substrate;
an interlayer dielectric film provided above the underlying layer;
a first contact hole provided in the interlayer dielectric film and reaching the underlying layer from an upper surface of the interlayer dielectric film;
a first alloy layer provided on a bottom portion of the first contact hole; and
a second alloy layer provided on a side wall of the first contact hole.

2. The semiconductor device according to claim 1, wherein
the first alloy layer includes an alloy layer formed as a result of reaction of polycrystalline deposited in the first contact hole.

3. The semiconductor device according to claim 1, wherein
the second alloy layer is an alloy layer formed as a result of reaction of polycrystalline deposited in the first contact hole.

4. The semiconductor device according to claim 1, wherein
a thickness of the second alloy layer is equal to or greater than 0.01 μm and equal to or smaller than 0.2 μm.

5. The semiconductor device according to claim 1, comprising
a first barrier metal layer provided inside the first alloy layer and the second alloy layer in the first contact hole.

6. The semiconductor device according to claim 5, wherein
the first barrier metal layer includes a TiN layer.

7. The semiconductor device according to claim 6, comprising
a plug layer of tungsten provided in contact with the first barrier metal layer in the first contact hole.

8. The semiconductor device according to claim 1, wherein
the semiconductor substrate includes a transistor portion and a diode portion.

9. The semiconductor device according to claim 1, wherein
the interlayer dielectric film further includes a second contact hole reaching the underlying layer from an upper surface of the interlayer dielectric film, and
the second contact hole does not include the second alloy layer on a side wall thereof.

10. The semiconductor device according to claim 1, comprising
an impurity-implanted polycrystalline layer provided in contact with the first alloy layer.

11. The semiconductor device according to claim 1, comprising:
an impurity-implanted polycrystalline layer at least provided between a lower surface of the first alloy layer and the underlying layer, wherein
a conductivity type of the underlying layer and that of the impurity-implanted polycrystalline layer are identical.

12. The semiconductor device according to claim 9, wherein:
a second barrier metal layer is provided in contact with the interlayer dielectric film on a side wall of the second contact hole.

13. The semiconductor device according to claim 1, wherein
the semiconductor substrate includes a recessed portion provided in the underlying layer below the first contact hole, and the first alloy layer is provided in the recessed portion.

14. The semiconductor device according to claim 1, wherein
at least a part of the semiconductor substrate includes a lifetime control region including a lifetime killer in a front surface side of the semiconductor substrate.

15. The semiconductor device according to claim 14, wherein
the semiconductor substrate includes a transistor portion and a diode portion, the transistor portion includes a main region spaced apart from the diode portion and a boundary region between the main region and the diode portion, and the lifetime control region is provided in the diode portion and the boundary region.

16. A manufacturing method of a semiconductor device, comprising:
forming an MOS gate structure on a front surface of a semiconductor substrate;
forming an interlayer dielectric film above an underlying layer provided on the front surface of the semiconductor substrate or above the semiconductor substrate;
forming a first contact hole in the interlayer dielectric film above the underlying layer reaching the underlying layer from an upper surface of the interlayer dielectric film;
depositing an initial polycrystalline film and a first initial metal film on an inner wall of the first contact hole; and
forming a first alloy layer on a bottom portion of the first contact hole and forming a second alloy layer on a side wall of the first contact hole, by heating the semiconductor substrate.

17. The manufacturing method of a semiconductor device according to claim 16, wherein
the initial polycrystalline film is deposited before depositing the first initial metal film.

18. The manufacturing method of a semiconductor device according to claim 16, wherein
the initial polycrystalline film is deposited after depositing the first initial metal film.

19. The manufacturing method of a semiconductor device according to claim 16, comprising:
forming a first barrier metal layer on the first alloy layer and the second alloy layer.

20. The manufacturing method of a semiconductor device according to claim 16, comprising:
depositing a second initial metal film before heating the semiconductor substrate.

21. A semiconductor device including an MOS gate structure, comprising:
an underlying layer provided on a front surface of a semiconductor substrate or above the semiconductor substrate;
an interlayer dielectric film provided above the underlying layer;
a second contact hole provided in the interlayer dielectric film and reaching the underlying layer from an upper surface of the interlayer dielectric film;
a third alloy layer provided on a bottom portion of the second contact hole; and
a second alloy layer provided on an upper surface of the interlayer dielectric film.

22. The semiconductor device according to claim 21, wherein
the third alloy layer includes an alloy layer formed as a result of reaction of the underlying layer.

23. The semiconductor device according to claim 21, wherein
a second barrier metal layer is provided in contact with the interlayer dielectric film on a side wall of the second contact hole.

24. The semiconductor device according to claim 23, wherein
the second barrier metal layer includes:
a Ti layer in contact with the interlayer dielectric film on the side wall of the second contact hole; and
a TiN layer stacked on the Ti layer.

25. The semiconductor device according to claim 22, comprising:
a first barrier metal layer provided on an upper surface of the third alloy layer.

26. The semiconductor device according to claim 25, wherein
the first barrier metal layer includes a TiN layer provided on the third alloy layer.

27. The semiconductor device according to claim 22, comprising:
a first barrier metal layer provided on an upper surface of the second alloy layer.

28. The semiconductor device according to claim 27, wherein
the first barrier metal layer includes a TiN layer provided on the second alloy layer.

29. A manufacturing method of a semiconductor device, comprising:
forming an MOS gate structure on a front surface of a semiconductor substrate;
forming an interlayer dielectric film above an underlying layer provided on a front surface of the semiconductor substrate or above the semiconductor substrate;
depositing an initial polycrystalline film on an upper surface of the interlayer dielectric film;
forming a second contact hole in the interlayer dielectric film reaching the underlying layer from an upper surface of the interlayer dielectric film;
depositing a first initial metal film on an inner wall of the second contact hole and on an upper surface of the initial polycrystalline film;
forming a third alloy layer on a bottom portion of the second contact hole and forming a second alloy layer on an upper surface of the interlayer dielectric film, by heating the semiconductor substrate.

30. The manufacturing method of a semiconductor device according to claim 29, comprising:
depositing a second initial metal film on the first initial metal film.
